(19) United States
(12) Patent Application Publication
(10) Pub. No.: US 2025/0185513 A1
(43) Pub. Date: Jun. 5, 2025

(54) THERMOELECTRIC CONVERSION ELEMENT

(71) Applicant: Panasonic Intellectual Property Management Co., Ltd., Osaka (JP)

(72) Inventors: Kouhei TAKAHASHI, Osaka (JP); Masaki FUJIKANE, Osaka (JP); Kunihiko NAKAMURA, Osaka (JP); Atsushi HIMENO, Osaka (JP); Naoki TAMBO, Kyoto (JP); Hiroyuki TANAKA, Nara (JP)

(21) Appl. No.: 19/049,600

(22) Filed: Feb. 10, 2025

Related U.S. Application Data
(63) Continuation of application No. PCT/JP2023/030823, filed on Aug. 25, 2023.

(30) Foreign Application Priority Data
Aug. 31, 2022 (JP) 2022-138386

(51) Int. Cl. H10N 10/17

(52) U.S. Cl. CPC H10N 10/17

(57) ABSTRACT

A thermoelectric conversion element includes a substrate and a plurality of thermocouples. Each of the thermocouples includes a thin-film-shaped p-type thermoelectric member and a thin-film-shaped n-type thermoelectric member arranged along a principal surface of the substrate. The thermoelectric conversion element generates a heat flow in a direction perpendicular to the principal surface of the substrate by a current in the thermocouples. In each of the thermocouples, the p-type thermoelectric member and the n-type thermoelectric member forming the thermocouple have a first side surface and a second side surface facing each other, respectively. The first side surface and the second side surface face each other in a plurality of different directions.

This application is a continuation of PCT/JP2023/030823 filed on Aug. 25, 2023, which claims foreign priority of Japanese Patent Application No. 2022-138386 filed on Aug. 31, 2022, the entire contents of both of which are incorporated herein by reference.

### BACKGROUND OF THE INVENTION

### 1. Field of the Invention

The present disclosure relates to a thermoelectric conversion element.

### 2. Description of Related Art

Thermoelectric conversion is a technology of directly converting heat energy to electric energy using the Seebeck effect in which an electromotive force is generated in proportion to a temperature difference applied between both ends of a material. Alternatively, thermoelectric conversion is a technology of converting electric energy to heat energy using the Peltier effect in which a temperature difference arises between both ends of a material by current generated in the material.

For example, WO2020/174764 describes that a thermoelectric conversion portion can be formed by an Si-based semiconductor material, and a thermoelectric conversion device including a thermoelectric conversion element can be formed on a base substrate such as an Si wafer.

In Bottner et al., “New Thermoelectric Components Using Microsystem Technologies”, Journal of Microelectromechanical Systems, 13, 414 (2004), it is described that a predetermined thermoelectric conversion device can be manufactured using an ordinary thin-film technology.

### SUMMARY OF THE INVENTION

The above technologies have room for reconsideration in terms of performance improvement of a thermoelectric conversion element. Accordingly, the present disclosure provides a technology that is advantageous in terms of performance improvement of a thermoelectric conversion element.

The present disclosure provides the following thermoelectric conversion element.

A thermoelectric conversion element including:
a substrate; and
a plurality of thermocouples each including a thin-film-shaped p-type thermoelectric member and a thin-film-shaped n-type thermoelectric member arranged along a principal surface of the substrate, wherein
the thermoelectric conversion element generates a heat flow in a direction perpendicular to the principal surface of the substrate by a current in the thermocouples, and
in each of the thermocouples,
   the p-type thermoelectric member and the n-type thermoelectric member have a first side surface and a second side surface, respectively, and
   the first side surface and the second side surface face each other in a plurality of different directions.

With the thermoelectric conversion element of the present disclosure, non-uniformity of the current density in the thin-film-shaped thermoelectric members is likely to become low, thus providing an advantage in terms of performance improvement of a thermoelectric conversion element.

### BRIEF DESCRIPTION OF THE DRAWINGS

FIG. 1A is a plan view showing an example of a thermoelectric conversion element of embodiment 1.

FIG. 1B is a plan view showing another example of the thermoelectric conversion element of embodiment 1.

FIG. 1C is a plan view showing still another example of the thermoelectric conversion element of embodiment 1.

FIG. 1D is a plan view showing still another example of the thermoelectric conversion element of embodiment 1.

FIG. 1E is a plan view showing still another example of the thermoelectric conversion element of embodiment 1.

FIG. 1F is a plan view showing still another example of the thermoelectric conversion element of embodiment 1.

FIG. 1G is a plan view showing still another example of the thermoelectric conversion element of embodiment 1.

FIG. 1H is a plan view showing still another example of the thermoelectric conversion element of embodiment 1.

FIG. 2 is another plan view of the thermoelectric conversion element shown in FIG. 1A.

FIG. 3A is a sectional view of the thermoelectric conversion element taken along line IIIA-IIIA in FIG. 2.

FIG. 3B is a sectional view of the thermoelectric conversion element taken along line IIIB-IIIB in FIG. 2.

FIG. 4A is a sectional view of the thermoelectric conversion element taken along line IVA-IVA in FIG. 3A.

FIG. 4B is a sectional view of the thermoelectric conversion element taken along line IVB-IVB in FIG. 3A.

FIG. 4C is a sectional view of the thermoelectric conversion element taken along line IVC-IVC in FIG. 3A.

FIG. 5 is another plan view of the thermoelectric conversion element shown in FIG. 1B.

FIG. 6A is a sectional view of the thermoelectric conversion element taken along line VIA-VIA in FIG. 5.

FIG. 6B is a sectional view of the thermoelectric conversion element taken along line VIB-VIB in FIG. 5.

FIG. 7A is a sectional view of the thermoelectric conversion element taken along line VIIA-VIIA in FIG. 6A.

FIG. 7B is a sectional view of the thermoelectric conversion element taken along line VIIB-VIIB in FIG. 6A.

FIG. 7C is a sectional view of the thermoelectric conversion element taken along line VIIC-VIIC in FIG. 6A.

FIG. 7D is a sectional view of the thermoelectric conversion element taken along line VIID-VIID in FIG. 6A.

FIG. 8 is another plan view of the thermoelectric conversion element shown in FIG. 1G.

FIG. 9A is a sectional view of the thermoelectric conversion element taken along line IXA-IXA in FIG. 8.

FIG. 9B is a sectional view of the thermoelectric conversion element taken along line IXB-IXB in FIG. 8.

FIG. 10A is a sectional view of the thermoelectric conversion element taken along line XA-XA in FIG. 9A.

FIG. 10B is a sectional view of the thermoelectric conversion element taken along line XB-XB in FIG. 9A.

FIG. 10C is a sectional view of the thermoelectric conversion element taken along line XC-XC in FIG. 9A.

FIG. 11A is a sectional view showing a method for manufacturing the thermoelectric conversion element of embodiment 1.

FIG. 11B is a sectional view showing the method for manufacturing the thermoelectric conversion element of embodiment 1.

FIG. 11C is a sectional view showing the method for manufacturing the thermoelectric conversion element of embodiment 1.

FIG. 11D is a sectional view showing the method for manufacturing the thermoelectric conversion element of embodiment 1.

FIG. 11E is a sectional view showing the method for manufacturing the thermoelectric conversion element of embodiment 1.

FIG. 11F is a sectional view showing the method for manufacturing the thermoelectric conversion element of embodiment 1.

FIG. 11G is a sectional view showing the method for manufacturing the thermoelectric conversion element of embodiment 1.

FIG. 11H is a sectional view showing the method for manufacturing the thermoelectric conversion element of embodiment 1.

FIG. 11I is a sectional view showing the method for manufacturing the thermoelectric conversion element of embodiment 1.

FIG. 11J is a sectional view showing the method for manufacturing the thermoelectric conversion element of embodiment 1.

FIG. 11K is a sectional view showing the method for manufacturing the thermoelectric conversion element of embodiment 1.

FIG. 11L is a sectional view showing the method for manufacturing the thermoelectric conversion element of embodiment 1.

FIG. 11M is a sectional view showing the method for manufacturing the thermoelectric conversion element of embodiment 1.

FIG. 11N is a sectional view showing the method for manufacturing the thermoelectric conversion element of embodiment 1.

FIG. 12A is a plan view showing an example of a thermoelectric conversion element of embodiment 2.

FIG. 12B is a plan view showing another example of the thermoelectric conversion element of embodiment 2.

FIG. 12C is a plan view showing still another example of the thermoelectric conversion element of embodiment 2.

FIG. 12D is a plan view showing still another example of the thermoelectric conversion element of embodiment 2.

FIG. 12E is a plan view showing still another example of the thermoelectric conversion element of embodiment 2.

FIG. 12F is a plan view showing still another example of the thermoelectric conversion element of embodiment 2.

FIG. 12G is a plan view showing still another example of the thermoelectric conversion element of embodiment 2.

FIG. 12H is a plan view showing still another example of the thermoelectric conversion element of embodiment 2.

FIG. 13 is another plan view of the thermoelectric conversion element shown in FIG. 12A.

FIG. 14A is a sectional view of the thermoelectric conversion element taken along line XIVA-XIVA in FIG. 13.

FIG. 14B is a sectional view of the thermoelectric conversion element taken along line XIVB-XIVB in FIG. 13.

FIG. 15A is a sectional view of the thermoelectric conversion element taken along line XVA-XVA in FIG. 14A.

FIG. 15B is a sectional view of the thermoelectric conversion element taken along line XVB-XVB in FIG. 14A.

FIG. 15C is a sectional view of the thermoelectric conversion element taken along line XVC-XVC in FIG. 14A.

FIG. 16A is a sectional view showing a method for manufacturing the thermoelectric conversion element of embodiment 2.

FIG. 16B is a sectional view showing the method for manufacturing the thermoelectric conversion element of embodiment 2.

FIG. 16C is a sectional view showing the method for manufacturing the thermoelectric conversion element of embodiment 2.

FIG. 16D is a sectional view showing the method for manufacturing the thermoelectric conversion element of embodiment 2.

FIG. 16E is a sectional view showing the method for manufacturing the thermoelectric conversion element of embodiment 2.

FIG. 16F is a sectional view showing the method for manufacturing the thermoelectric conversion element of embodiment 2.

FIG. 16G is a sectional view showing the method for manufacturing the thermoelectric conversion element of embodiment 2.

FIG. 16H is a sectional view showing the method for manufacturing the thermoelectric conversion element of embodiment 2.

FIG. 16I is a sectional view showing the method for manufacturing the thermoelectric conversion element of embodiment 2.

FIG. 16J is a sectional view showing the method for manufacturing the thermoelectric conversion element of embodiment 2.

### DETAILED DESCRIPTION

### Finding on Which the Present Disclosure Is Based

It is conceivable to manufacture a thermoelectric conversion element including thin-film-shaped thermoelectric members by applying a semiconductor manufacturing process. Such a thermoelectric conversion element has advantages that, for example, the density of a disposed thermocouple is high, size reduction or weight reduction is easily achieved, and automation of the manufacturing process is easy, as compared to a bulk thermoelectric conversion element manufactured through a process including cutting and the like.

The thermoelectric conversion element includes, for example, a substrate, and a first wiring, a second wiring, a p-type thermoelectric member, and an n-type thermoelectric member formed on the substrate. One-end surfaces of the p-type thermoelectric member and the n-type thermoelectric member are electrically connected to the first wiring, and other-end surfaces of the p-type thermoelectric member and the n-type thermoelectric member are electrically connected to the second wiring, whereby one thermocouple is formed.

In the thermoelectric conversion element, the first wiring and the second wiring serve to generate a current between the p-type thermoelectric member and the n-type thermoelectric member adjacent to each other, and inside the wirings, the current is generated in a direction parallel to a principal surface of the substrate. Meanwhile, the p-type thermoelectric member and the n-type thermoelectric member serve to generate a current between the first wiring and the second wiring, and inside these members, the current is generated in a direction perpendicular to the principal surface of the substrate.

In the thermoelectric conversion element, a case where the p-type thermoelectric member and the n-type thermoelectric member forming one thermocouple face each other in a single direction in a plan view, is assumed. In this case, electric charges for generating a current in a direction parallel to the principal surface of the substrate inside the first wiring and the second wiring move toward the p-type thermoelectric member and the n-type thermoelectric member along the direction in which the p-type thermoelectric member and the n-type thermoelectric member face each other. Thereafter, inside the p-type thermoelectric member and the n-type thermoelectric member, the direction of the current changes to the direction perpendicular to the principal surface of the substrate. In a case where the ratio of the dimension of the thermoelectric member in the direction perpendicular to the principal surface of the substrate to a width which is the dimension of the thermoelectric member in a direction parallel to the principal surface of the substrate is sufficiently great, the current density inside the thermoelectric member can be uniformed. On the other hand, in a case where the above ratio is small in the thermoelectric member, the current density of the thermoelectric member becomes high at an end in one direction in which electric charges enter or exit, so that the current density inside the thermoelectric member is likely to become non-uniform. Due to the non-uniform current density inside the thermoelectric member, the state of heat absorption and the state of heat generation caused by the Peltier effect become non-uniform at the surface of the thermoelectric member, so that the performance of the thermoelectric conversion element can become low.

In the bulk thermoelectric conversion element, the above ratio is comparatively great and the current density inside the thermoelectric member is likely to become uniform. On the other hand, in the thermoelectric conversion element, in a case where the thermoelectric member has a thin-film shape, the above ratio can become considerably small. For example, the width of the thermoelectric member is several tens of micrometers, whereas the thickness of the thermoelectric member which is the dimension of the thermoelectric member in a direction perpendicular to the principal surface of the substrate is several micrometers or smaller, and thus the above ratio can become 0.1 or smaller. Therefore, in the thermoelectric conversion element including the thin-film-shaped thermoelectric member, the current density in the thermoelectric member is likely to become non-uniform, and this cannot be considered advantageous in terms of performance improvement.

Accordingly, for the thermoelectric conversion element including the thin-film-shaped thermoelectric member, the present inventors have studied intensively on a configuration that can reduce non-uniformity of the current density in the thin-film-shaped thermoelectric member, and thus have finally completed the thermoelectric conversion element of the present disclosure.

### Embodiments of the Present Disclosure

Hereinafter, embodiments of the present disclosure will be described with reference to the drawings. The embodiments described below are all comprehensive or specific examples. The numerical values, shapes, materials, components, arrangement positions of the components, connection forms, process conditions, steps, order of the steps, etc., shown in the following embodiments are examples, and are not intended to limit the present disclosure. In addition, among the components in the following embodiments, the components that are not described in the independent claims that represent broadest concepts are described as discretionary components. Each drawing is a schematic diagram, and is not necessarily exactly illustrated.

### Embodiment 1

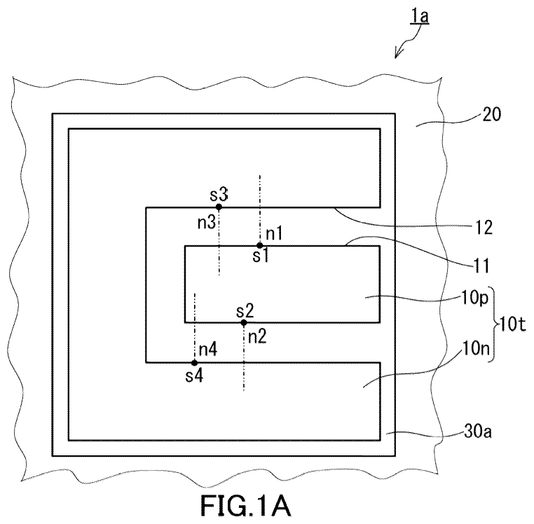

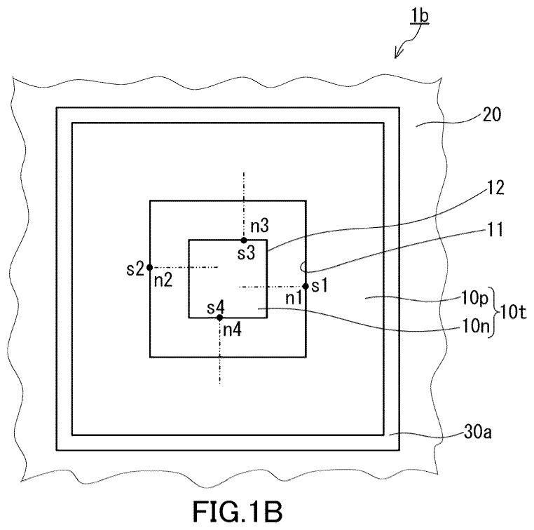

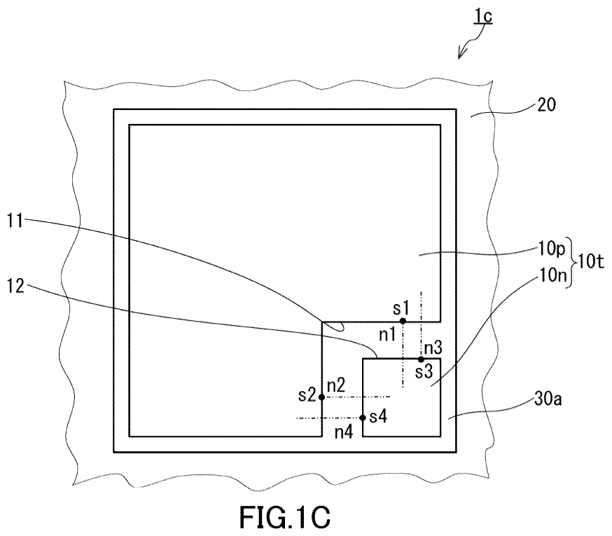

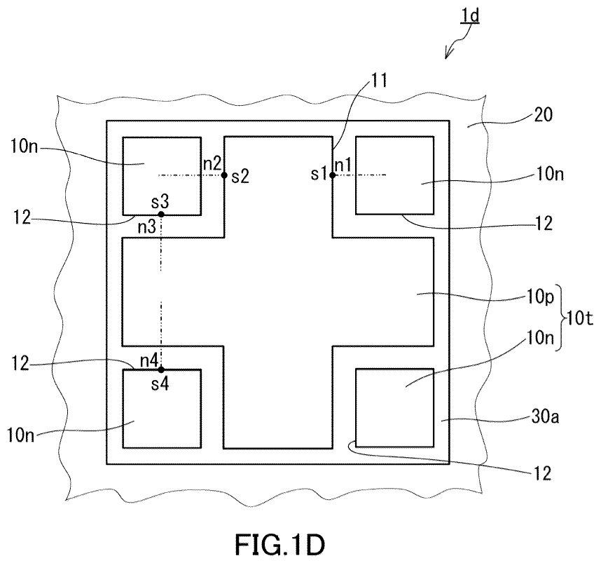

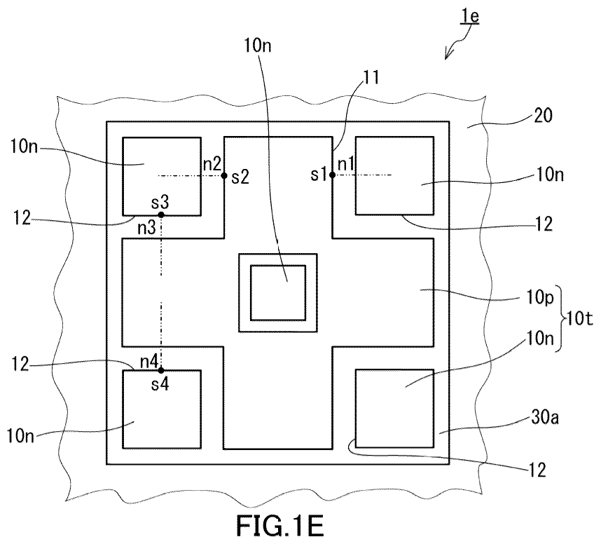

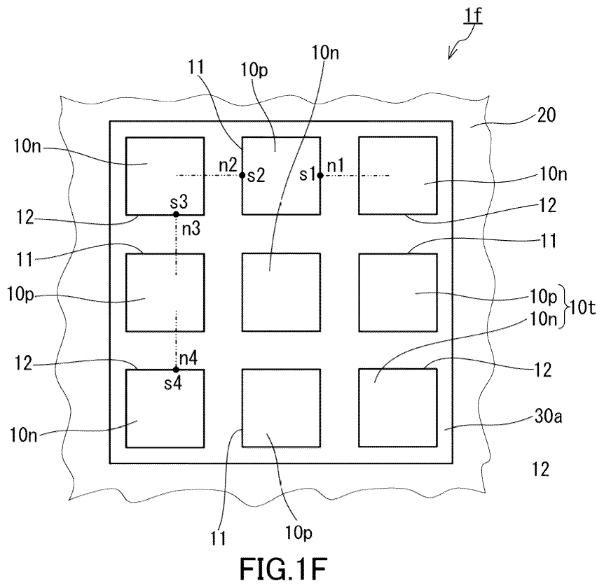

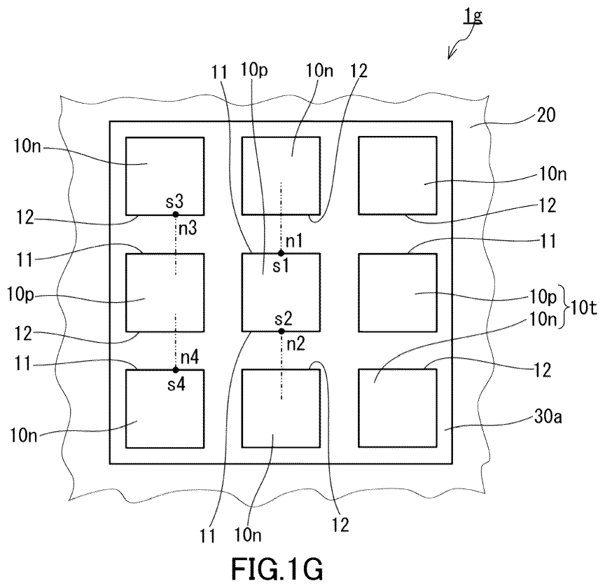

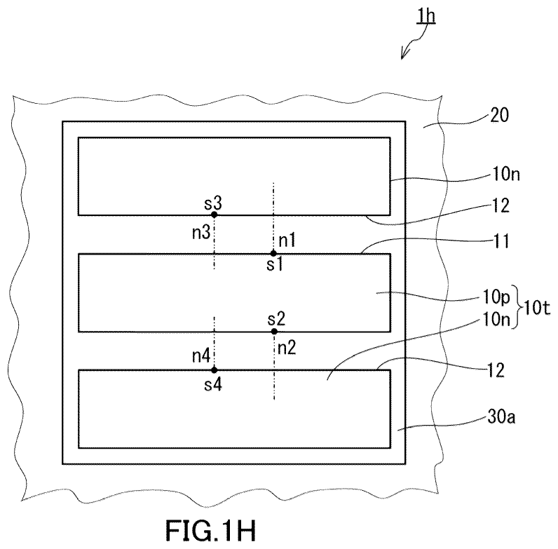

FIG. 1A is a plan view showing an example of a thermoelectric conversion element of embodiment 1. As shown in FIG. 1A, a thermoelectric conversion element 1a includes a substrate 20 and a thermocouple 10t. The thermocouple 10t includes a thin-film-shaped p-type thermoelectric member 10p and a thin-film-shaped n-type thermoelectric member 10n arranged along a principal surface of the substrate 20. In FIG. 1A, the p-type thermoelectric member 10p and the n-type thermoelectric member 10n form one thermocouple 10t. The thermoelectric conversion element 1a generates a heat flow in a direction perpendicular to the principal surface of the substrate 20 by a current in the thermocouple 10t. The p-type thermoelectric member 10p and the n-type thermoelectric member 10n have a first side surface 11 and a second side surface 12, respectively. The first side surface 11 and the second side surface 12 face each other in a plurality of different directions. With this configuration, electric charges flow into the p-type thermoelectric member 10p and the n-type thermoelectric member 10n from a plurality of directions. As a result, non-uniformity of the current densities in the p-type thermoelectric member 10p and the n-type thermoelectric member 10n is likely to become low. The first side surface 11 and the second side surface 12 may face each other with a solid present therebetween.

As long as the first side surface 11 and the second side surface 12 face each other in a plurality of different directions, the different directions are not limited to a specific combination of directions. The thermoelectric conversion element of embodiment 1 satisfies at least one condition selected from the group consisting of the following (Ia) and (IIa), for example:
(Ia) a first normal n1 and a second normal n2 can be defined on the p-type thermoelectric member 10p,
the first normal n1 extends from a first point s1 of the first side surface 11 toward outside of the p-type thermoelectric member 10p, and intersects the second side surface 12,
the second normal n2 extends from a second point s2 different from the first point s1 of the first side surface 11 toward outside of the p-type thermoelectric member 10p, and intersects the second side surface 12, and
the second normal n2 extends in a direction having an angle that is 90 degrees or greater and 270 degrees or smaller counterclockwise with respect to the first normal n1 when the thermocouple 10t is seen in a plan view toward the substrate 20; and
(IIa) a third normal n3 and a fourth normal n4 can be defined on the n-type thermoelectric member 10n,
the third normal n3 extends from a third point s3 of the second side surface 12 toward outside of the n-type thermoelectric member 10n, and intersects the first side surface 11,
the fourth normal n4 extends from a fourth point s4 different from the third point s3 of the second side surface 12 toward outside of the n-type thermoelectric member 10n, and intersects the first side surface 11, and
the fourth normal n4 extends in a direction having an angle that is 90 degrees or greater and 270 degrees or smaller counterclockwise with respect to the third normal n3 when the thermocouple 10t is seen in a plan view toward the substrate 20.

With this configuration, the above angle regarding the first normal n1 and the second normal n2 or the above angle regarding the third normal n3 and the fourth normal n4 is likely to be adjusted into a desired range. Thus, non-uniformity of the current densities in the p-type thermoelectric member 10p and the n-type thermoelectric member 10n is more likely to become low.

As shown in FIG. 1A, the second normal n2 extends in a direction having an angle of 180 degrees counterclockwise with respect to the first normal n1 when the thermocouple 10t is seen in a plan view toward the substrate 20, for example. In the thermoelectric conversion element 1a, it is also possible to define the second normal n2 extending in a direction having an angle of 90 degrees counterclockwise with respect to the first normal n1 when the thermocouple 10t is seen in a plan view toward the substrate 20.

As shown in FIG. 1A, the fourth normal n4 extends in a direction having an angle of 180 degrees counterclockwise with respect to the third normal n3 when the thermocouple 10t is seen in a plan view toward the substrate 20, for example. In the thermoelectric conversion element 1a, it is also possible to define the fourth normal n4 extending in a direction having an angle of 90 degrees counterclockwise with respect to the third normal n3 when the thermocouple 10t is seen in a plan view toward the substrate 20.

As shown in FIG. 1A, the first side surface 11 and the second side surface 12 face each other in three different directions. The first side surface 11 and the second side surface 12 each have a pair of portions that face in directions parallel and opposite to each other, and a portion located between the pair of portions and extending in a direction perpendicular to the pair of portions.

FIG. 1B is a plan view showing another example of the thermoelectric conversion element of embodiment 1. A thermoelectric conversion element 1b shown in FIG. 1B is configured in the same manner as the thermoelectric conversion element 1a, except for specifically described parts. As shown in FIG. 1B, in the thermoelectric conversion element 1b, the first side surface 11 and the second side surface 12 face each other in four different directions. The first side surface 11 and the second side surface 12 each have two pairs of portions that face in directions parallel and opposite to each other.

As shown in FIG. 1B, in the thermoelectric conversion element 1b, the second normal n2 extends in a direction having an angle of 180 degrees counterclockwise with respect to the first normal n1 when the thermocouple 10t is seen in a plan view toward the substrate 20, for example. In the thermoelectric conversion element 1b, it is also possible to define the second normal n2 extending in a direction having an angle of 90 degrees or 270 degrees counterclockwise with respect to the first normal n1 when the thermocouple 10t is seen in a plan view toward the substrate 20.

In the thermoelectric conversion element 1b, the fourth normal n4 extends in a direction having an angle of 180 degrees counterclockwise with respect to the third normal n3 when the thermocouple 10t is seen in a plan view toward the substrate 20, for example. In the thermoelectric conversion element 1a, it is also possible to define the fourth normal n4 extending in a direction having an angle of 90 degrees or 270 degrees counterclockwise with respect to the third normal n3 when the thermocouple 10t is seen in a plan view toward the substrate 20.

FIG. 1C is a plan view showing still another example of the thermoelectric conversion element of embodiment 1. A thermoelectric conversion element 1c shown in FIG. 1C is configured in the same manner as the thermoelectric conversion element 1a, except for specifically described parts. As shown in FIG. 1C, in the thermoelectric conversion element 1c, the first side surface 11 and the second side surface 12 face each other in two different directions. The first side surface 11 and the second side surface 12 each have a pair of portions that extend in directions perpendicular to each other.

As shown in FIG. 1C, in the thermoelectric conversion element 1c, the second normal n2 extends in a direction having an angle of 90 degrees counterclockwise with respect to the first normal n1 when the thermocouple 10t is seen in a plan view toward the substrate 20, for example. In the thermoelectric conversion element 1c, the fourth normal n4 extends in a direction having an angle of 90 degrees counterclockwise with respect to the third normal n3 when the thermocouple 10t is seen in a plan view toward the substrate 20, for example.

FIG. 1D, FIG. 1E, FIG. 1F, FIG. 1G, and FIG. 1H are plan views showing still other examples of the thermoelectric conversion element of embodiment 1. Thermoelectric conversion elements 1d, 1e, 1f, 1g, and 1h respectively shown in FIG. 1D, FIG. 1E, FIG. 1F, FIG. 1G, and FIG. 1H are configured in the same manner as the thermoelectric conversion element 1a, except for specifically described parts.

As shown in the thermoelectric conversion elements 1d, 1e, 1f, 1g, and 1h, at least one selected from the group consisting of the p-type thermoelectric member 10p and the n-type thermoelectric member 10n forming one thermocouple 10t may be formed of a plurality of portions separated from each other. In this case, at least one side surface selected from the group consisting of the first side surface 11 and the second side surface 12 may include a plurality of portions separated from each other. For example, in the thermoelectric conversion elements 1d, 1e, and 1h, the n-type thermoelectric member 10n including the portions separated from each other, and one p-type thermoelectric member 10p, form one thermocouple 10t. In the thermoelectric conversion elements 1f and 1g, the n-type thermoelectric member 10n including the portions separated from each other, and the p-type thermoelectric member 10p including the portions separated from each other, form one thermocouple 10t. In a case where the p-type thermoelectric member 10p of one thermocouple 10t includes the portions separated from each other, the portions are connected electrically and thermally in parallel in the thermocouple 10t. Meanwhile, in one thermocouple 10t, the portions separated from each other of the p-type thermoelectric member 10p are connected electrically in series to the n-type thermoelectric member 10n and connected thermally in parallel thereto. In a case where the n-type thermoelectric member 10n of one thermocouple 10t includes the portions separated from each other, the portions are connected electrically and thermally in parallel in the thermocouple 10t. Meanwhile, in one thermocouple 10t, the portions separated from each other of the n-type thermoelectric member 10n are connected electrically in series to the p-type thermoelectric member 10p and connected thermally in parallel thereto.

The thermoelectric conversion element of embodiment 1 may be configured such that the arrangement and the shape of the p-type thermoelectric member 10p and the arrangement and the shape of the n-type thermoelectric member 10n are replaced with each other in the examples shown in FIG. 1A to FIG. 1H.

As shown in FIG. 1A to FIG. 1H, in a plan view of the thermocouple 10t, at least one portion of at least one thermoelectric member selected from the group consisting of the p-type thermoelectric member 10p and the n-type thermoelectric member 10n has a quadrangular outline, for example. At least one portion of at least one thermoelectric member selected from the group consisting of the p-type thermoelectric member 10p and the n-type thermoelectric member 10n may have a triangular outline, a pentagonal outline, another polygonal outline, or a circular outline, for example, in a plan view of the thermocouple 10t.

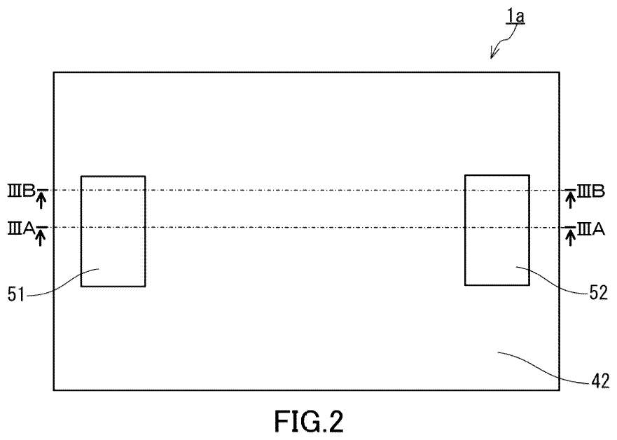

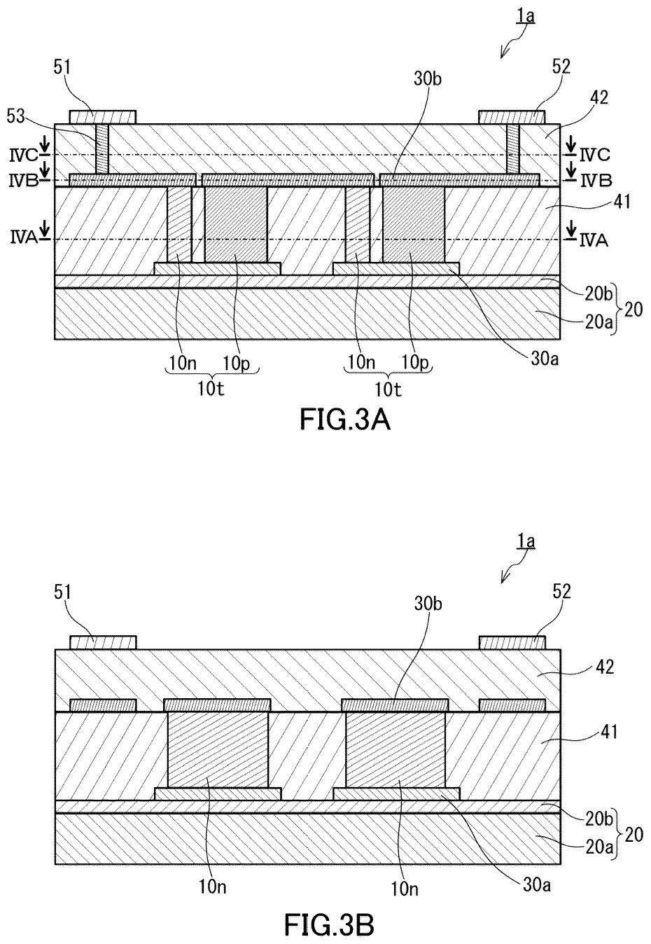

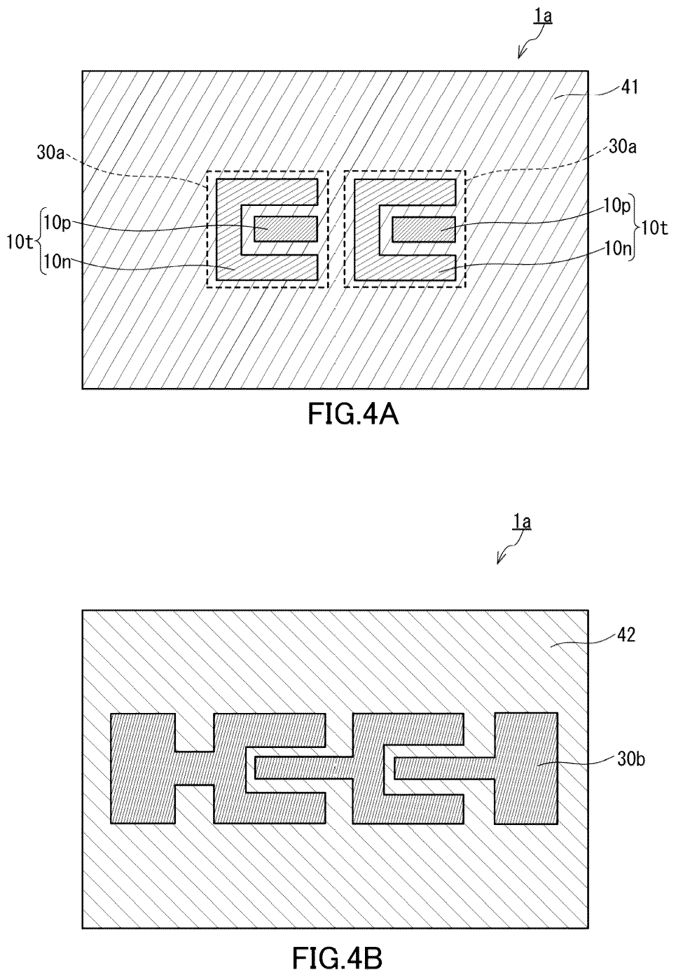

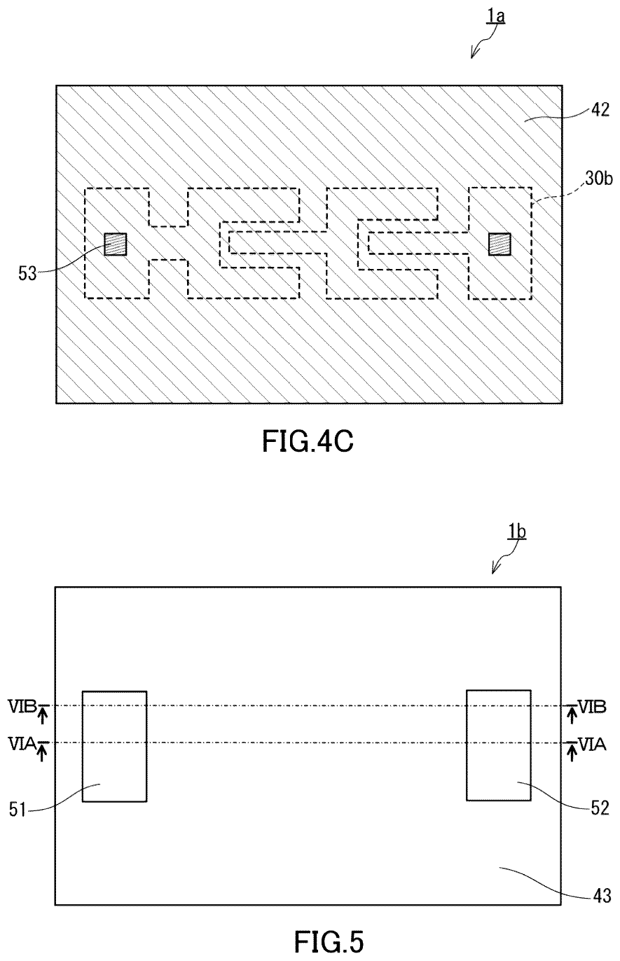

FIG. 2 is another plan view showing the thermoelectric conversion element 1a. FIG. 3A and FIG. 3B are sectional views of the thermoelectric conversion element 1a taken along line IIIA-IIIA and line IIIB-IIIB in FIG. 2, respectively. FIG. 4A, FIG. 4B, and FIG. 4C are sectional views of the thermoelectric conversion element 1a taken along line IVA-IVA, line IVB-IVB, and line IVC-IVC in FIG. 3A, respectively.

As shown in FIG. 3A and FIG. 3B, in the thermoelectric conversion element 1a, the substrate 20 includes a base 20a and a foundation insulation film 20b, for example. A first wiring 30a is disposed on the foundation insulation film 20b. The p-type thermoelectric members 10p and the n-type thermoelectric members 10n are disposed on the first wiring 30a. Each p-type thermoelectric member 10p contains a thermoelectric material having a positive Seebeck coefficient, for example. Each n-type thermoelectric member 10n contains a thermoelectric material having a negative Seebeck coefficient, for example. A second wiring 30b is disposed on the p-type thermoelectric members 10p and the n-type thermoelectric members 10n. One-end surfaces in the thickness direction of the p-type thermoelectric members 10p and the n-type thermoelectric members 10n are electrically connected to the first wiring 30a. Other-end surfaces in the thickness direction of the p-type thermoelectric members 10p and the n-type thermoelectric members 10n are electrically connected to the second wiring 30b. The p-type thermoelectric members 10p and the n-type thermoelectric members 10n are connected electrically in series via the first wiring 30a and the second wiring 30b. Thus, the thermocouples 10t are formed.

The thermoelectric conversion element 1a further includes a first interlayer insulation film 41 and a second interlayer insulation film 42, for example. The first interlayer insulation film 41 is disposed between the first wiring 30a and the second wiring 30b. The first interlayer insulation film 41 is formed so as to fill a gap between the p-type thermoelectric member 10p and the n-type thermoelectric member 10n, and a space around the p-type thermoelectric member 10p and the n-type thermoelectric member 10n in a plan view of the thermocouple 10t. The second interlayer insulation film 42 covers the second wiring 30b. As shown in FIG. 3A, the thermoelectric conversion element 1a further includes a plurality of plugs 53, for example. The second interlayer insulation film 42 is formed so as to fill a gap between the plugs 53. The plugs 53 extend through the second interlayer insulation films 42 and are electrically connected to the second wiring 30b. As shown in FIG. 2 and FIG. 3A, a first electrode pad 51 and a second electrode pad 52 are disposed on the second interlayer insulation film 42. The first electrode pad 51 and the second electrode pad 52 are electrically connected to different plugs 53, respectively. Thus, between the first electrode pad 51 and the second electrode pad 52, the thermocouples 10t are electrically connected to the first electrode pad 51 and the second electrode pad 52.

A material forming the base 20a is not limited to a specific material. The base 20a is an Si substrate, for example. The base 20a may be formed by a semiconductor other than Si or a material other than a semiconductor.

A material forming the foundation insulation film 20b is not limited to a specific material. The foundation insulation film 20b may contain an oxide insulator such as silicon oxide and aluminum oxide, or a nitride insulator such as silicon nitride and aluminum nitride. In a case where the base 20a has an electric insulation property, the foundation insulation film 20b may be omitted. The thickness of the foundation insulation film 20b is not limited to a specific value. The thickness may be 50 nm to 1 μm, for example.

Materials forming the first wiring 30a and the second wiring 30b are not limited to specific materials as long as the materials have a predetermined electric conductivity. The first wiring 30a and the second wiring 30b contain an impurity semiconductor, metal, or a metal compound, for example. Examples of the metal and the metal compound are materials, such as Al, Cu, TiN, and TaN, used in a semiconductor manufacturing process. The thicknesses of the first wiring 30a and the second wiring 30b are not limited to specific values. The thicknesses are 100 nm to 1 μm, for example.

Materials forming the p-type thermoelectric member 10p and the n-type thermoelectric member 10n are not limited to specific materials. The materials are semiconductor materials in which carriers serving for electric conduction can be adjusted to either holes or electrons by doping, for example. Such semiconductor materials are not limited to specific materials. Examples of such semiconductor materials are Si, SiGe, SiC, GaAs, InAs, InSb, InP, GaN, ZnO, and BiTe. Materials forming the p-type thermoelectric member 10p and the n-type thermoelectric member 10n may be a single-crystal material, a polycrystal material, or an amorphous material. Base materials forming the p-type thermoelectric member 10p and the n-type thermoelectric member 10n may be the same material or different materials. The thicknesses of the p-type thermoelectric member 10p and the n-type thermoelectric member 10n are not limited to specific values. The thicknesses are 100 nm or greater and 10 μm or smaller, for example. The carrier densities in the p-type thermoelectric member 10p and the n-type thermoelectric member 10n are not limited to specific values. The carrier densities are in a range of 1×10¹⁹ cm⁻³ to 1×10²¹ cm⁻³, for example.

Materials forming the first interlayer insulation film 41 and the second interlayer insulation film 42 are not limited to specific materials. The first interlayer insulation film 41 and the second interlayer insulation film 42 may contain an oxide insulator such as silicon oxide and aluminum oxide, or a nitride insulator such as silicon nitride and aluminum nitride. Materials forming the first interlayer insulation film 41 and the second interlayer insulation film 42 may be a single-crystal material, a polycrystal material, or an amorphous material. Materials forming the first interlayer insulation film 41 and the second interlayer insulation film 42 may be the same kind of material or different kinds of materials. The thickness of the first interlayer insulation film 41 may vary in accordance with the thicknesses of the p-type thermoelectric member 10p and the n-type thermoelectric member 10n. The thickness of the first interlayer insulation film 41 is 100 nm to 10 μm, for example. The thickness of the second interlayer insulation film 42 is not limited to a specific value as long as the second interlayer insulation film 42 can cover the second wiring 30b. The thickness is 100 nm to 2 μm, for example.

Materials forming the plug 53, the first electrode pad 51, and the second electrode pad 52 are not limited to specific materials. The materials are metal or a metal compound, for example. The metal and the metal compound may be materials, such as Al, Cu, W, TiN, and TaN, used in a semiconductor manufacturing process, for example.

As shown in FIG. 3A, the thermoelectric conversion element 1a includes a plurality of the thermocouples 10t. In the thermoelectric conversion element 1a, the thermocouples 10t are connected electrically in series between the first electrode pad 51 and the second electrode pad 52.

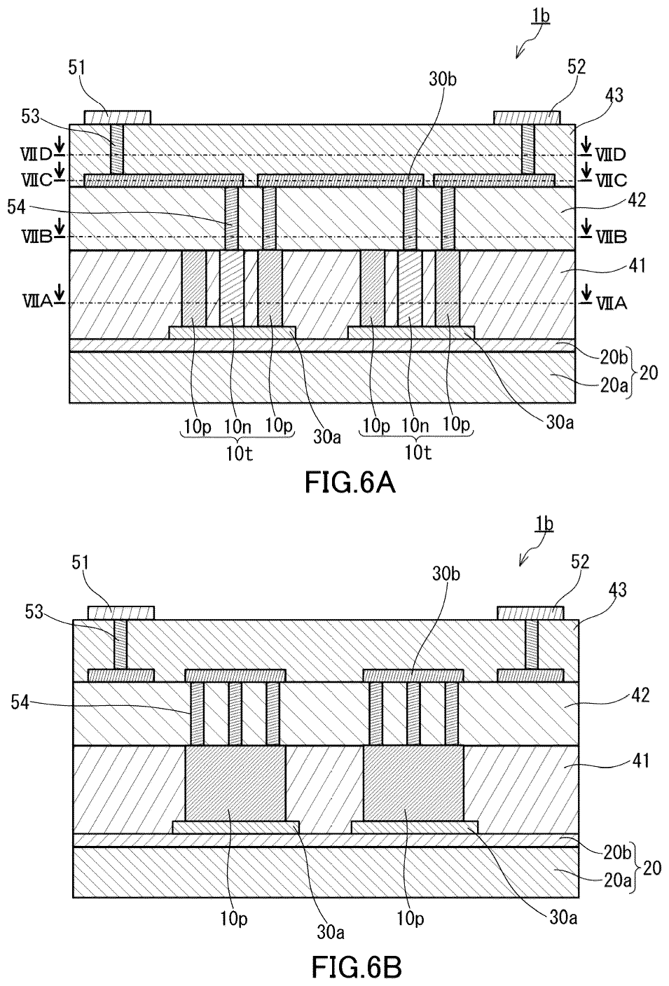

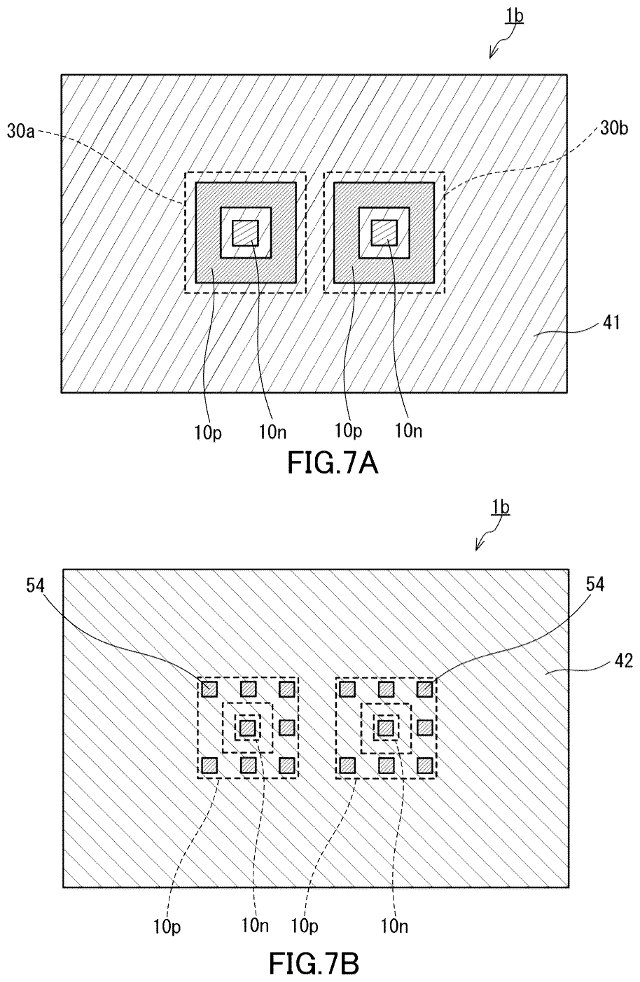

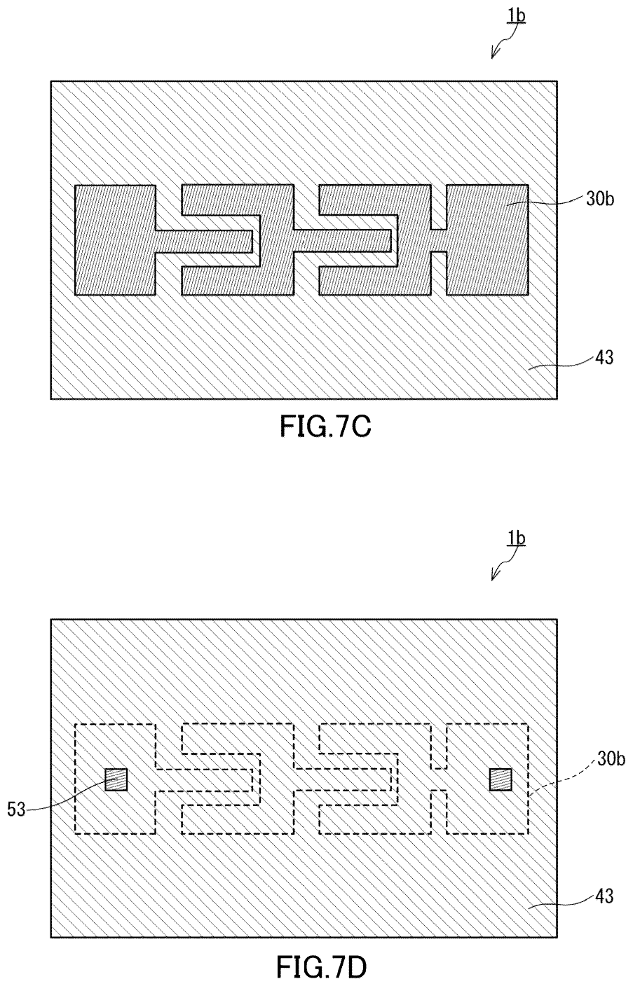

FIG. 5 is another plan view showing the thermoelectric conversion element 1b. FIG. 6A and FIG. 6B are sectional views of the thermoelectric conversion element 1b taken along line VIA-VIA and line VIB-VIB in FIG. 5, respectively. FIG. 7A, FIG. 7B, FIG. 7C, and FIG. 7D are sectional views of the thermoelectric conversion element 1b taken along line VIIA-VIIA, line VIIB-VIIB, line VIIC-VIIC, and line VIID-VIID in FIG. 6A, respectively. The thermoelectric conversion element 1b is configured in the same manner as the thermoelectric conversion element 1a, except for specifically described parts.

As shown in FIG. 6A, the thermocouples 10t are connected electrically in series in the thermoelectric conversion element 1b. As shown in FIG. 7A, each p-type thermoelectric member 10p is formed in an annular shape in a plan view of the thermocouple 10t. On the other hand, the n-type thermoelectric member 10n is disposed in a space surrounded by the p-type thermoelectric member 10p. The n-type thermoelectric member 10n of one thermocouple 10t is electrically connected to the p-type thermoelectric member 10p of another thermocouple 10t adjacent across the p-type thermoelectric member 10p that forms the one thermocouple 10t together with the above n-type thermoelectric member 10n. Thus, the thermocouples 10t can be connected electrically in series.

As shown in FIG. 6A, in the thermoelectric conversion element 1b, the second wiring 30b forms a layer separately from the p-type thermoelectric members 10p and the n-type thermoelectric members 10n, and the adjacent thermocouples 10t are electrically connected via plugs 54. A material forming the plugs 54 is not limited to a specific material. The material is metal or a metal compound, for example. The metal and the metal compound may be materials, such as Al, Cu, W, TiN, and TaN, used in a semiconductor manufacturing process, for example. A gap between the plugs 54 is filled with the second interlayer insulation film 42.

As shown in FIG. 6A, the thermoelectric conversion element 1b includes a third interlayer insulation film 43. The third interlayer insulation film 43 covers the second wiring 30b. A material forming the third interlayer insulation film 43 is an electric insulator such as silicon oxide, and the material may be the same kind as or a different kind from the material forming the first interlayer insulation film 41 or the second interlayer insulation film 42. The third interlayer insulation film 43 is formed so as to fill a gap between the plugs 53. The plugs 53 extend through the third interlayer insulation film 43 and are electrically connected to the second wiring 30b. Thus, layers are laminated, whereby the thermocouples 10t are connected electrically in series.

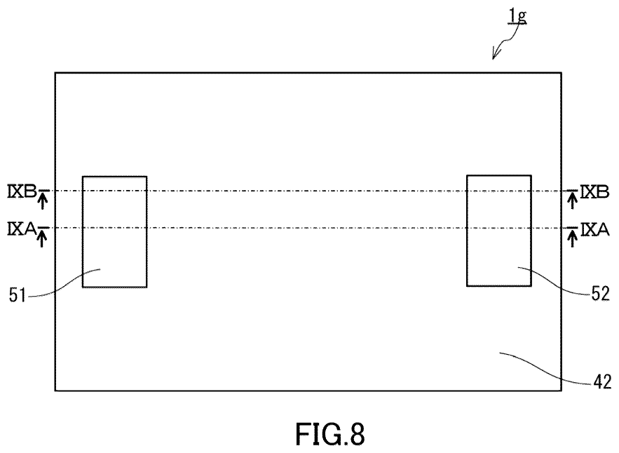

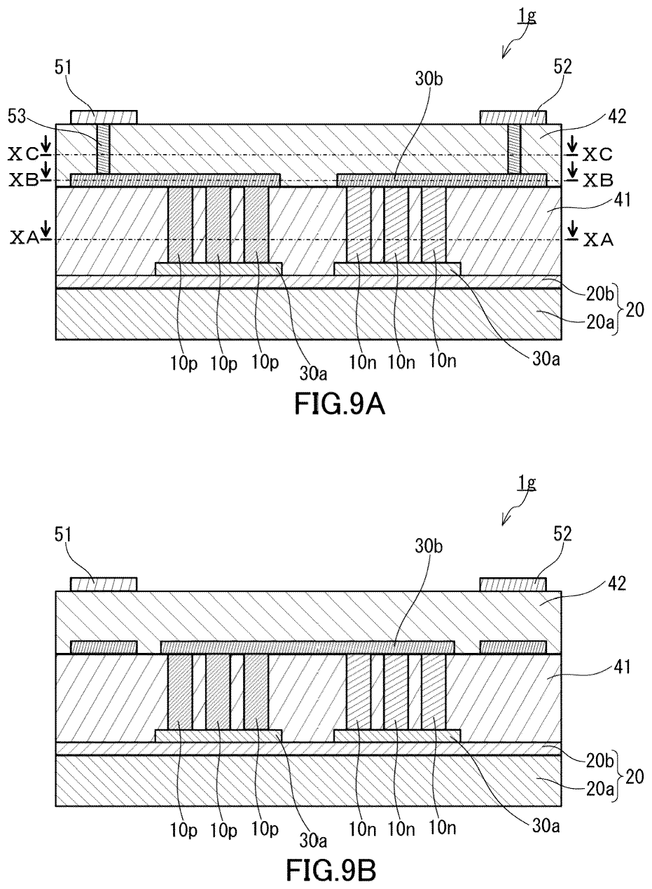

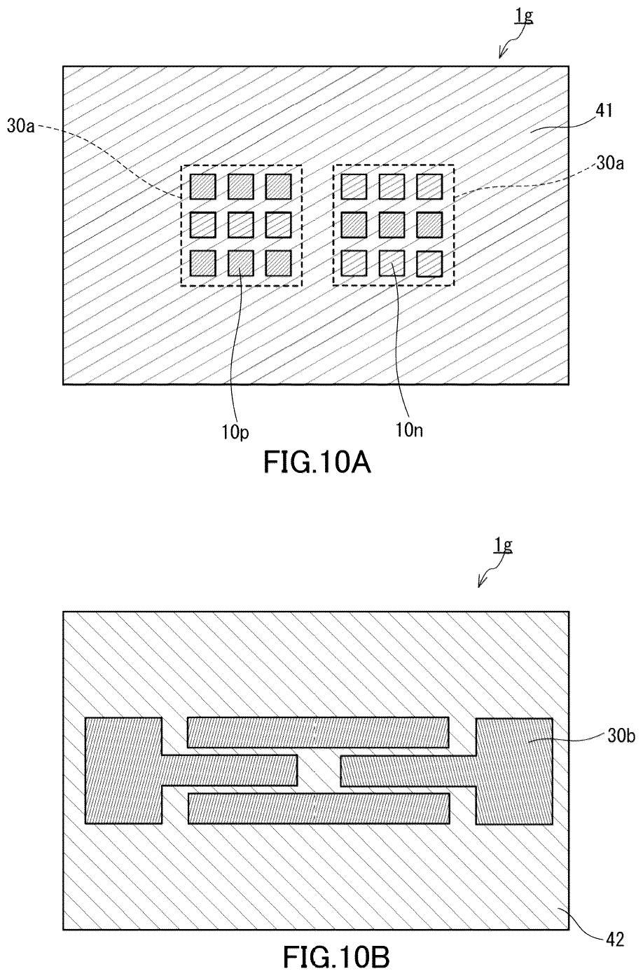

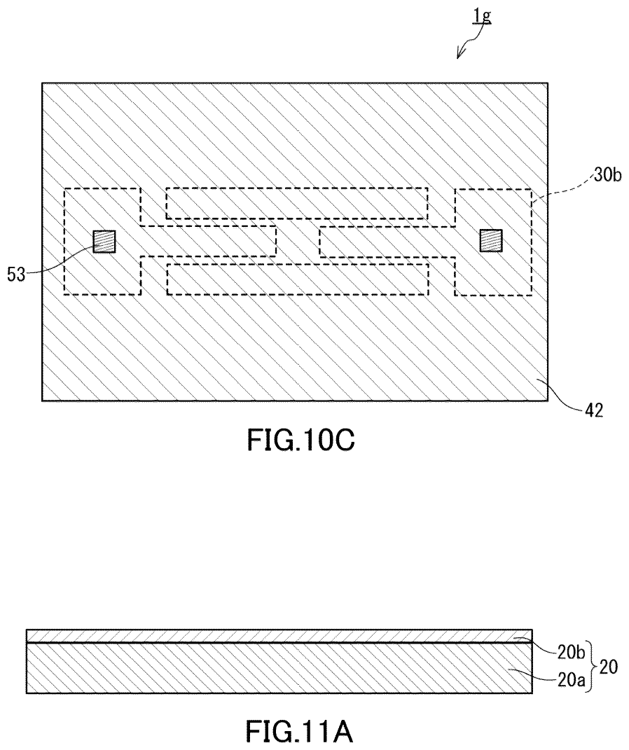

FIG. 8 is another plan view showing the thermoelectric conversion element 1g. FIG. 9A and FIG. 9B are sectional views of the thermoelectric conversion element 1g taken along line IXA-IXA and line IXB-IXB in FIG. 8, respectively. FIG. 10A, FIG. 10B, and FIG. 10C are sectional views of the thermoelectric conversion element 1g taken along line XA-XA, line XB-XB, and line XC-XC in FIG. 9A, respectively. The thermoelectric conversion element 1g is configured in the same manner as the thermoelectric conversion element 1a, except for specifically described parts.

The thermoelectric conversion element 1g includes a plurality of thermocouples 10t. As shown in FIG. 9A and FIG. 9B, in each thermocouple 10t, the p-type thermoelectric member 10p has a plurality of portions separated from each other, and the n-type thermoelectric member 10n has a plurality of portions separated from each other. In the thermoelectric conversion element 1g, the thermocouples 10t are connected electrically in series. The portions separated from each other of the p-type thermoelectric member 10p are connected electrically and thermally in parallel in one thermocouple 10t. The portions separated from each other of the n-type thermoelectric member 10n are connected electrically and thermally in parallel in one thermocouple 10t. Meanwhile, in one thermocouple 10t, the portions separated from each other of the p-type thermoelectric member 10p are connected electrically in series to the portions separated from each other of the n-type thermoelectric member 10n and connected thermally in parallel thereto.

As shown in FIG. 10A, FIG. 10B, and FIG. 10C, layers are laminated, whereby the thermocouples 10t are connected electrically in series in the thermoelectric conversion element 1g.

In the thermoelectric conversion element of embodiment 1, when a temperature difference arises in the direction perpendicular to the principal surface of the substrate 20, an electromotive force is generated between the first electrode pad 51 and the second electrode pad 52 by the Seebeck effect. Through conductive wires connected to the first electrode pad 51 and the second electrode pad 52, the electromotive force is outputted to outside of the thermoelectric conversion element. Thus, the thermoelectric conversion element can be used as an electric generation device and a heat flow sensor.

In the thermoelectric conversion element of embodiment 1, when conductive wires are connected to the first electrode pad 51 and the second electrode pad 52 and a current is generated, a heat flow in the direction perpendicular to the principal surface of the substrate 20 can be generated by the Peltier effect. The direction of the heat flow can change depending on the direction of the current. Thus, the thermoelectric conversion element of embodiment 1 can be used as a temperature control device for cooling or heating.

An example of a method for manufacturing the thermoelectric conversion element of embodiment 1 will be described. The method for manufacturing the thermoelectric conversion element will be described using the thermoelectric conversion element 1b as an example. The method for manufacturing the thermoelectric conversion element 1b is not limited to the following method. The thermoelectric conversion elements 1a and 1g can be manufactured by the same method as the method for manufacturing the thermoelectric conversion element 1b.

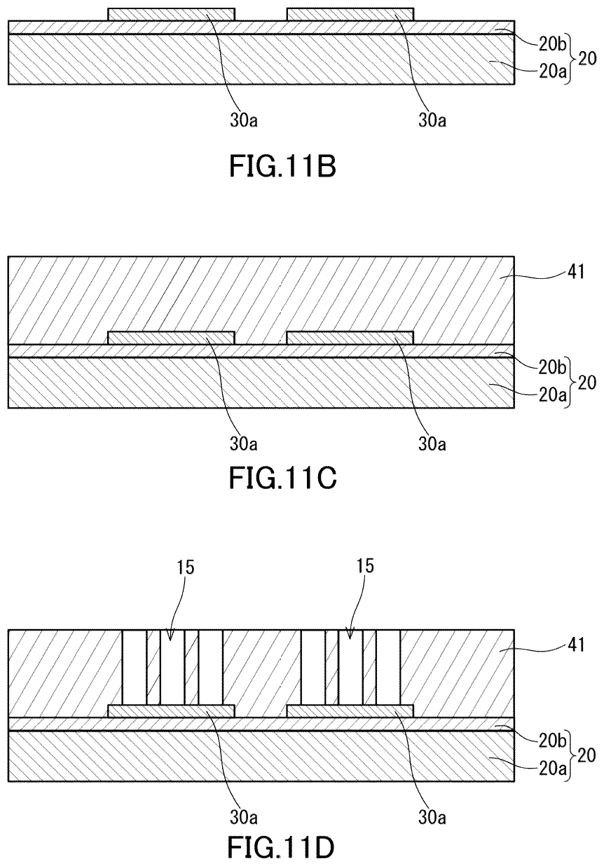

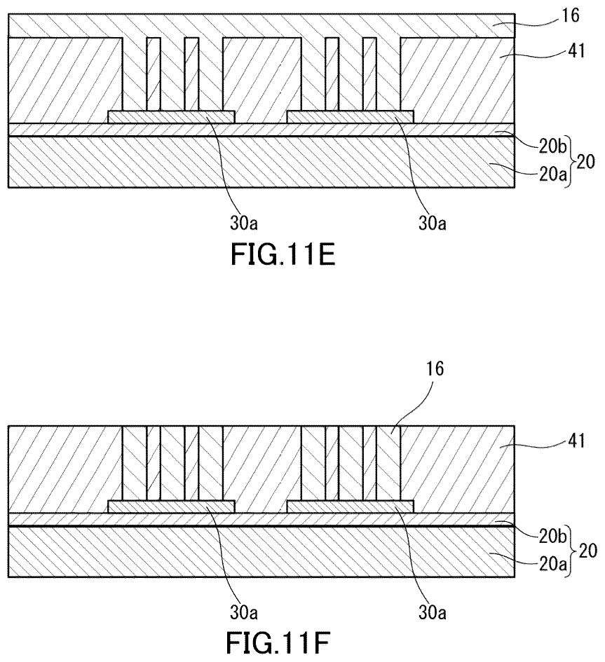

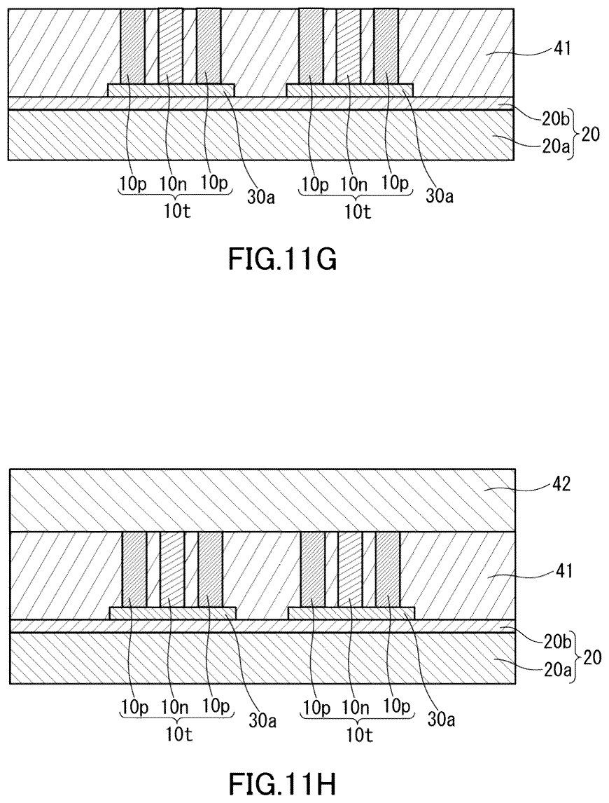

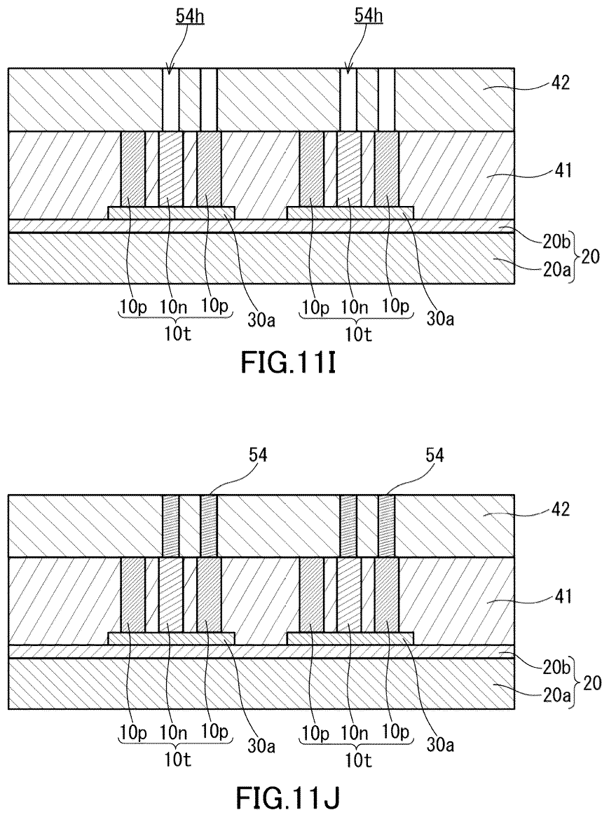

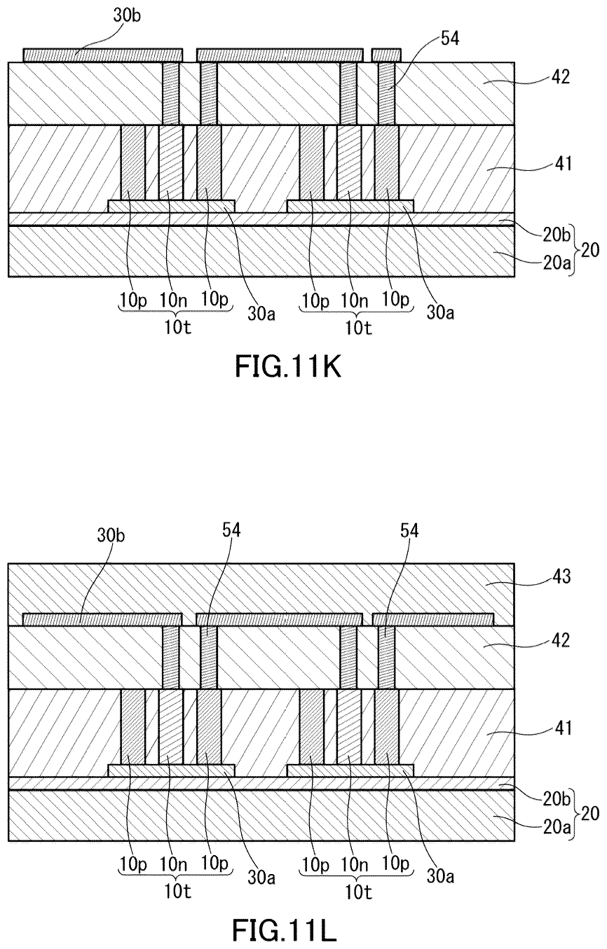

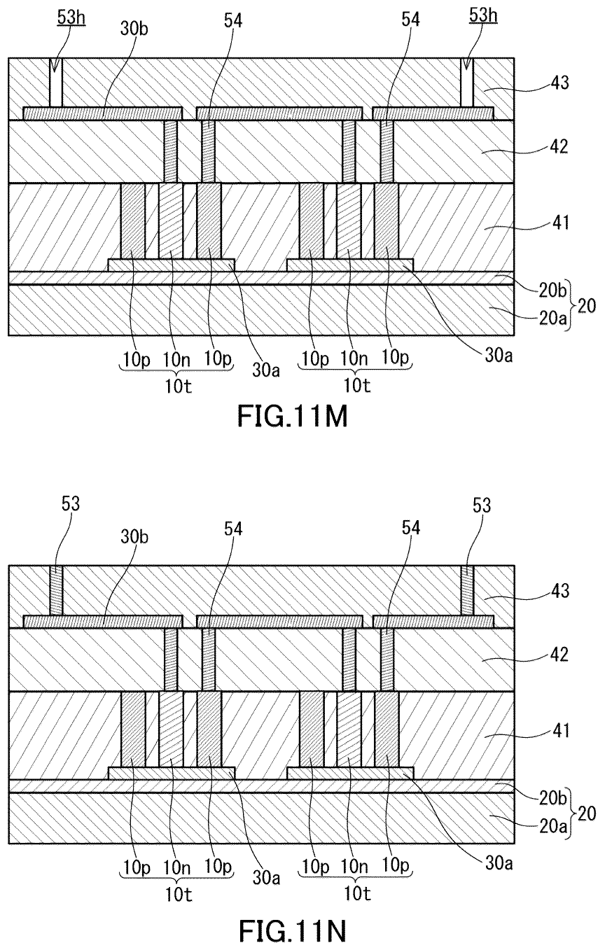

As shown in FIG. 11A, the foundation insulation film 20b made of an electric insulator such as SiO₂ is formed on a surface of the base 20a by a method such as sputtering and chemical vapor deposition (CVD), whereby the substrate 20 is obtained. Next, as shown in FIG. 11B, the first wiring 30a made of an electric conductor such as Al is formed. For example, a pattern to be the first wiring 30a is formed by photolithography and etching, or lift-off, from a film of Al or the like formed by a method such as sputtering.

Next, as shown in FIG. 11C, the first interlayer insulation film 41 is formed by a method such as sputtering and CVD, so as to cover the first wiring 30a. Next, as shown in FIG. 11D, recesses 15 are formed in the first interlayer insulation film 41 by photolithography and etching. At this stage, parts of the first wiring 30a are exposed so as to form bottom surfaces of the recesses 15. Next, as shown in FIG. 11E, a thermoelectric material thin film 16 made of a semiconductor such as polycrystal Si is formed by a method such as sputtering and CVD from above the first interlayer insulation film 41, so that the recesses 15 are filled with the thermoelectric material thin film 16. Next, as shown in FIG. 11F, the thermoelectric material thin film 16 outside the recesses 15 is removed by a method such as chemical mechanical polishing (CMP). Next, as shown in FIG. 11G, doping is performed in predetermined areas, whereby the p-type thermoelectric members 10p and the n-type thermoelectric members 10n are obtained. For the doping, a method such as ion implantation is used. An annealing treatment may be additionally performed to adjust the carrier density into a desired range.

Next, as shown in FIG. 11H, the second interlayer insulation film 42 is formed so as to cover the p-type thermoelectric members 10p, the n-type thermoelectric members 10n, and the first interlayer insulation film 41. The second interlayer insulation film 42 is formed by a method such as sputtering and CVD. Next, as shown in FIG. 11I, recesses 54h are formed in the second interlayer insulation film 42 by photolithography and etching. At this stage, a part of an end surface of the p-type thermoelectric member 10p or a part of an end surface of the n-type thermoelectric member 10n is exposed so as to form a bottom surface of each recess 54h. Next, a film of a material such as Al and TiN is formed by a method such as sputtering and CVD from above the second interlayer insulation film 42. Next, as shown in FIG. 11J, the film outside the recesses 54h is removed by a method such as CMP, whereby the plugs 54 are formed inside the second interlayer insulation film 42.

Next, as shown in FIG. 11K, the second wiring 30b made of an electric conductor such as Al is formed. A pattern to be the second wiring 30b is formed by photolithography and etching, or lift-off, etc., from a film of Al or the like formed by a method such as sputtering. Next, as shown in FIG. 11L, the third interlayer insulation film 43 made of an electric insulation material such as SiO₂ is formed by a method such as sputtering and CVD, so as to cover the second wiring 30b. Next, as shown in FIG. 11M, recesses 53h are formed in the third interlayer insulation film 43 by photolithography and etching. At this stage, parts of the second wiring 30b are exposed so as to form bottom surfaces of the recesses 53h. Next, a film of a material such as Al and TiN is formed by a method such as sputtering and CVD from above the third interlayer insulation film 43, and the film outside the recesses 53h is removed by a method such as CMP. Thus, as shown in FIG. 11N, the plugs 53 are formed inside the third interlayer insulation film 43. Finally, a metal thin film containing a material such as Al is formed from above the third interlayer insulation film 43, and the first electrode pad 51 and the second electrode pad 52 are formed by lift-off, or photolithography and etching. Thus, the thermoelectric conversion element 1b is obtained.

While the foundation insulation film 20b, the first interlayer insulation film 41, the second interlayer insulation film 42, and the third interlayer insulation film 43 are formed by different materials, only the first interlayer insulation film 41 may be finally removed by etching. For example, the first interlayer insulation film 41 may be formed by SiO₂, and the foundation insulation film 20b, the second interlayer insulation film 42, and the third interlayer insulation film 43 may be formed by Al₂O₃. Then, SiO₂ may be etched by gas-phase hydrofluoric acid, to remove the first interlayer insulation film 41. Owing to removal of the first interlayer insulation film 41 around the p-type thermoelectric member 10p and the n-type thermoelectric member 10n, a temperature difference arising between a one-end surface and an other-end surface of each of the p-type thermoelectric member 10p and the n-type thermoelectric member 10n is likely to become great. As a result, the performance of the thermoelectric conversion element is likely to become higher.

### Embodiment 2

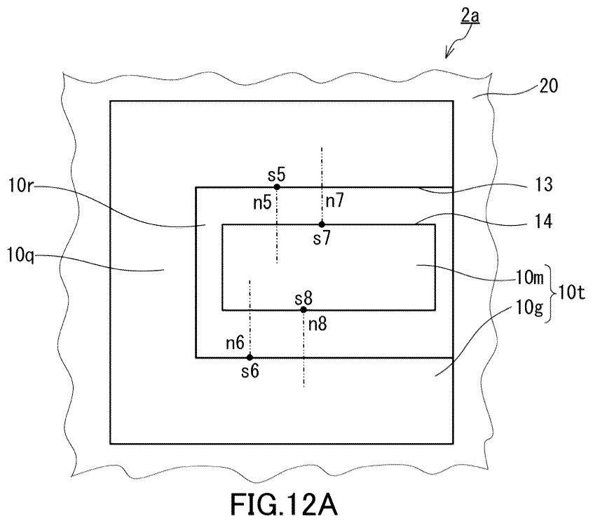

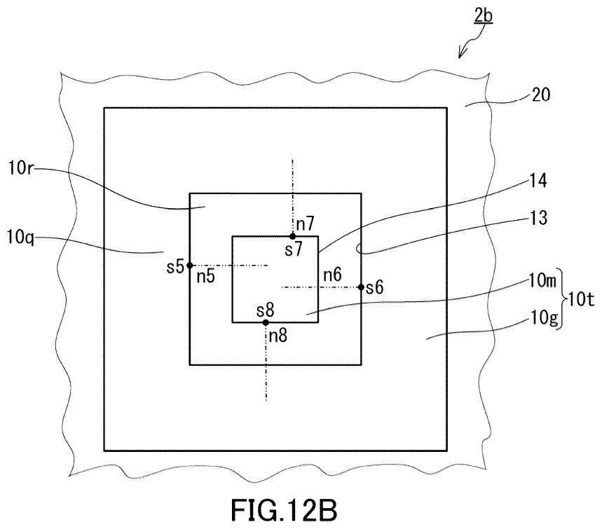

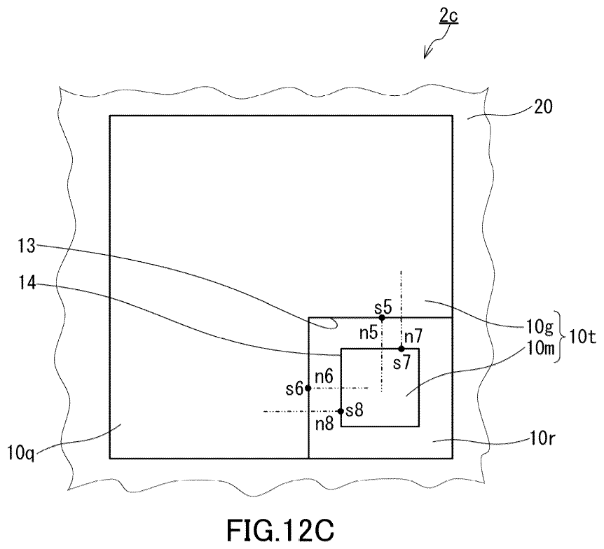

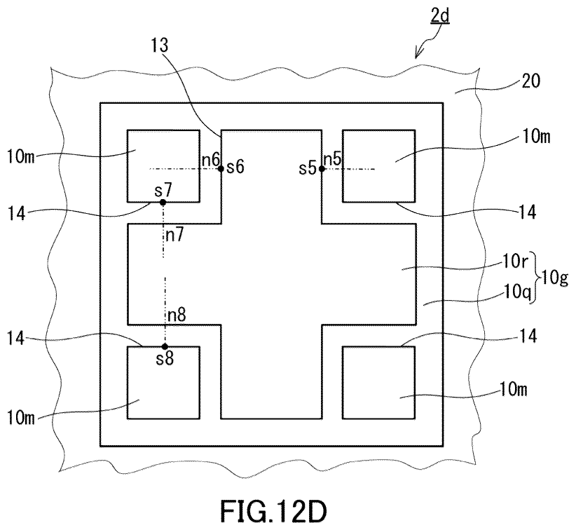

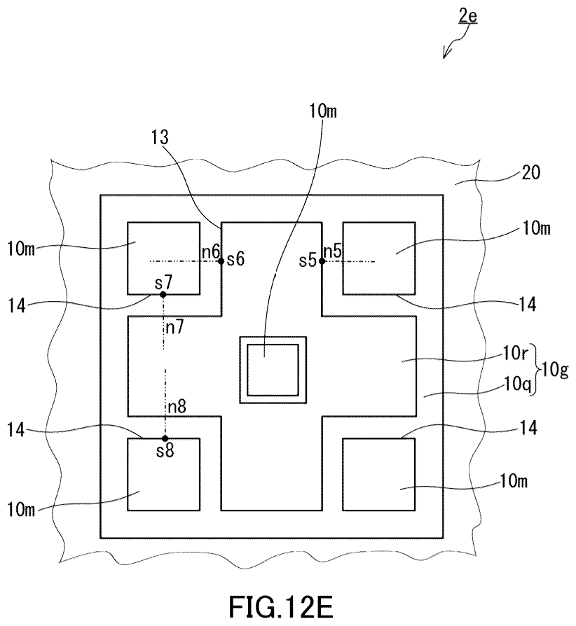

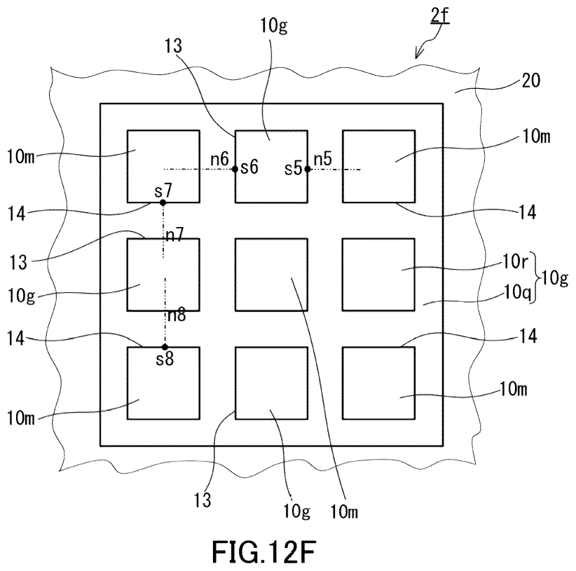

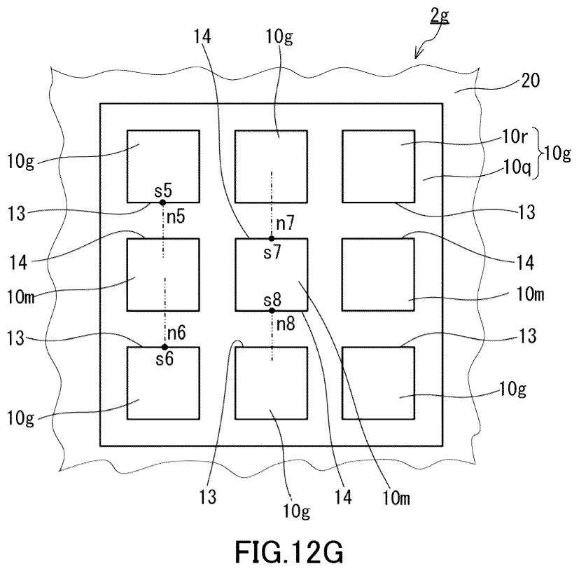

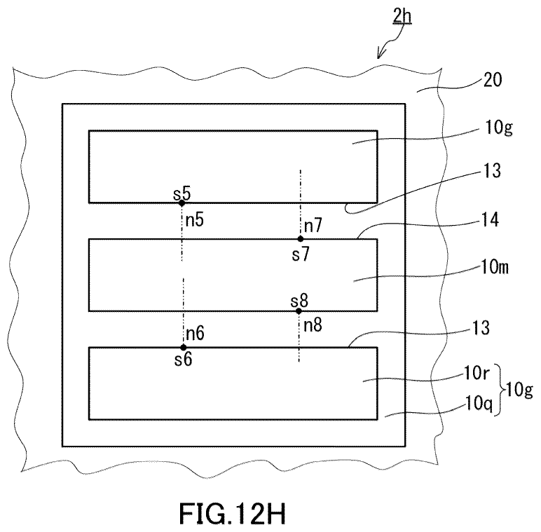

FIG. 12A is a plan view showing an example of a thermoelectric conversion element of embodiment 2. The thermoelectric conversion element of embodiment 2 may be configured in the same manner as the thermoelectric conversion element of embodiment 1, except for specifically described parts. In embodiment 2, components that are the same as or correspond to those of the thermoelectric conversion element of embodiment 1 are denoted by the same reference characters and the detailed description thereof is omitted. The description regarding the thermoelectric conversion element of embodiment 1 also applies to the thermoelectric conversion element of embodiment 2, unless there is technical contradiction therebetween.

The thermoelectric conversion element of embodiment 2 is a thermoelectric conversion element of a uni-leg type. As shown in FIG. 12A, the thermoelectric conversion element 2a includes the substrate 20 and the thermocouple 10t. The thermocouple 10t includes a thin-film-shaped thermoelectric member 10g and an electroconductive member 10m arranged along the principal surface of the substrate 20. The electroconductive member 10m contains at least one selected from the group consisting of metal and a metal compound. The thermoelectric conversion element 2a generates a heat flow in the direction perpendicular to the principal surface of the substrate 20 by a current in the thermocouple 10t. As shown in FIG. 12A, the thermoelectric member 10g and the electroconductive member 10m forming one thermocouple 10t have a first side surface 13 and a second side surface 14, respectively. The first side surface 13 and the second side surface 14 face each other in a plurality of different directions. With this configuration, electric charges flow into the thermoelectric member 10g and the electroconductive member 10m from a plurality of directions. As a result, non-uniformity of the current densities in the thermoelectric member 10g and the electroconductive member 10m is likely to become low. The first side surface 13 and the second side surface 14 may face each other with a solid present therebetween. The thermoelectric member 10g may be a p-type thermoelectric member or an n-type thermoelectric member.

The thermoelectric conversion element of a uni-leg type which is the thermoelectric conversion element of embodiment 2 satisfies at least one condition selected from the group consisting of the following (Ib) and (IIb), for example:
(Ib) a first normal n5 and a second normal n6 can be defined on the thermoelectric member 10g,
the first normal n5 extends from a first point s5 of the first side surface 13 toward outside of the thermoelectric member 10g, and intersects the second side surface 14,
the second normal n6 extends from a second point s6 different from the first point s5 of the first side surface 13 toward outside of the thermoelectric member 10g, and intersects the second side surface 14, and
the second normal n6 extends in a direction having an angle that is 90 degrees or greater and 270 degrees or smaller counterclockwise with respect to the first normal n5 when the thermocouple 10t is seen in a plan view toward the substrate 20; and
(IIb) a third normal n7 and a fourth normal n8 can be defined on the electroconductive member 10m,
the third normal n7 extends from a third point s7 of the second side surface 14 toward outside of the electroconductive member 10m, and intersects the first side surface 13,
the fourth normal n8 extends from a fourth point s8 different from the third point s7 of the second side surface 14 toward outside of the electroconductive member 10m, and intersects the first side surface 13, and
the fourth normal n8 extends in a direction having an angle that is 90 degrees or greater and 270 degrees or smaller counterclockwise with respect to the third normal n7 when the thermocouple 10t is seen in a plan view toward the substrate 20.

With this configuration, the above angle regarding the first normal n5 and the second normal n6 or the above angle regarding the third normal n7 and the fourth normal n8 is likely to be adjusted into a desired range. Thus, non-uniformity of the current densities in the thermoelectric member 10g and the electroconductive member 10m is more likely to become low.

As shown in FIG. 12A, the thermoelectric member 10g has a first portion 10q and a second portion 10r. The first portion 10q has a first thickness. The second portion 10r has a second thickness smaller than the first thickness. In the thermoelectric member 10g, a step is formed by the first portion 10q and the second portion 10r. With this configuration, for example, a configuration corresponding to the first wiring 30a of the thermoelectric conversion element of embodiment 1 can be omitted, whereby the configuration of the thermoelectric conversion element is likely to be simplified. In addition, by the second portion 10r, electric charges can enter or exit the first portion 10q from a plurality of directions, whereby non-uniformity of the current density inside the thermoelectric member 10g is likely to become low.

The electroconductive member 10m is disposed on the second portion 10r, for example. With this configuration, electric connection between the electroconductive member 10m and the thermoelectric member 10g can be ensured even if a configuration corresponding to the first wiring 30a of the thermoelectric conversion element of embodiment 1 is omitted.

The second portion 10r serves a role equivalent to the first wiring 30a in the thermoelectric conversion element of embodiment 1. The second thickness of the second portion 10r is not limited to a specific value as long as the second thickness is smaller than the first thickness. The second thickness is, for example, 10 nm or greater, and desirably 100 nm or greater.

The thermoelectric conversion element of embodiment 2 may have a configuration in which one of the p-type thermoelectric member 10p and the n-type thermoelectric member 10n of the thermocouple 10t shown in any of the thermoelectric conversion elements 1a to 1h is replaced with the electroconductive member 10m.

As shown in FIG. 12A, in the thermoelectric conversion element 2a, the first side surface 13 and the second side surface 14 face each other in three different directions.

As shown in FIG. 12A, the second normal n6 extends in a direction having an angle of 180 degrees counterclockwise with respect to the first normal n5 when the thermocouple 10t is seen in a plan view toward the substrate 20, for example. In the thermoelectric conversion element 2a, it is also possible to define the second normal n6 extending in a direction having an angle of 90 degrees counterclockwise with respect to the first normal n5 when the thermocouple 10t is seen in a plan view toward the substrate 20.

As shown in FIG. 12A, the fourth normal n8 extends in a direction having an angle of 180 degrees counterclockwise with respect to the third normal n7 when the thermocouple 10t is seen in a plan view toward the substrate 20, for example. In the thermoelectric conversion element 2a, it is also possible to define the fourth normal n8 extending in a direction having an angle of 90 degrees counterclockwise with respect to the third normal n7 when the thermocouple 10t is seen in a plan view toward the substrate 20.

FIG. 12B, FIG. 12C, FIG. 12D, FIG. 12E, FIG. 12F, FIG. 12G, and FIG. 12H are plan views showing other examples of the thermoelectric conversion element of embodiment 2.

As shown in FIG. 12B, the first side surface 13 and the second side surface 14 face each other in four different directions in the thermoelectric conversion element 2b. In the thermoelectric conversion element 2b, the second normal n6 extends in a direction having an angle of 180 degrees counterclockwise with respect to the first normal n5 when the thermocouple 10t is seen in a plan view toward the substrate 20, for example. In the thermoelectric conversion element 2b, it is also possible to define the second normal n6 extending in a direction having an angle of 90 degrees or 270 degrees counterclockwise with respect to the first normal n5 when the thermocouple 10t is seen in a plan view toward the substrate 20. In the thermoelectric conversion element 2b, the fourth normal n8 extends in a direction having an angle of 180 degrees counterclockwise with respect to the third normal n7 when the thermocouple 10t is seen in a plan view toward the substrate 20, for example. In the thermoelectric conversion element 2b, it is also possible to define the fourth normal n8 extending in a direction having an angle of 90 degrees or 270 degrees counterclockwise with respect to the third normal n7 when the thermocouple 10t is seen in a plan view toward the substrate 20.

As shown in FIG. 12C, in the thermoelectric conversion element 2c, the first side surface 13 and the second side surface 14 face each other in two different directions. In the thermoelectric conversion element 2b, the second normal n6 extends in a direction having an angle of 90 degrees counterclockwise with respect to the first normal n5 when the thermocouple 10t is seen in a plan view toward the substrate 20, for example. The fourth normal n8 extends in a direction having an angle of 90 degrees counterclockwise with respect to the third normal n7 when the thermocouple 10t is seen in a plan view toward the substrate 20, for example.

As shown in FIG. 12D to FIG. 12H, in thermoelectric conversion elements 2d to 2h, at least one selected from the group consisting of the thermoelectric member 10g and the electroconductive member 10m forming one thermocouple 10t may include a plurality of portions separated from each other in a specific plane parallel to the principal surface of the substrate 20. In this case, at least one side surface selected from the group consisting of the first side surface 13 and the second side surface 14 may include a plurality of portions separated from each other. For example, in the thermoelectric conversion elements 2d, 2e, and 2h, the electroconductive member 10m including the portions separated from each other in the specific plane parallel to the principal surface of the substrate 20, and one thermoelectric member 10g, form one thermocouple 10t. In the thermoelectric conversion elements 2f and 2g, the thermoelectric member 10g including the portions separated from each other in the specific plane parallel to the principal surface of the substrate 20, and the electroconductive member 10m including the portions separated from each other in the specific plane parallel to the principal surface of the substrate 20, form one thermocouple 10t. In a case where the thermoelectric member 10g of one thermocouple 10t includes the portions separated from each other in the specific plane parallel to the principal surface of the substrate 20, the portions are connected electrically and thermally in parallel in the thermocouple 10t. Meanwhile, in one thermocouple 10t, the portions of the thermoelectric member 10g separated from each other in the specific plane parallel to the principal surface of the substrate 20 are connected electrically in series to the electroconductive member 10m and connected thermally in parallel thereto. In a case where the electroconductive member 10m of one thermocouple 10t includes the portions separated from each other in the specific plane parallel to the principal surface of the substrate 20, the portions are connected electrically and thermally in parallel to the thermocouple 10t. Meanwhile, in one thermocouple 10t, the portions of the electroconductive member 10m separated from each other in the specific plane parallel to the principal surface of the substrate 20 are connected electrically in series to the thermoelectric member 10g and connected thermally in parallel.

The thermoelectric conversion element of embodiment 2 may be configured such that the arrangement and the shape of the thermoelectric member 10g and the arrangement and the shape of the electroconductive member 10m are replaced with each other in the examples shown in FIG. 12A to FIG. 12H.

As shown in FIG. 12A to FIG. 12H, in a plan view of the thermocouple 10t, at least one portion of at least one selected from the group consisting of the thermoelectric member 10g and the electroconductive member 10m has a quadrangular outline, for example. At least one portion of at least one selected from the group consisting of the thermoelectric member 10g and the electroconductive member 10m may have a triangular outline, a pentagonal outline, another polygonal outline, or a circular outline, for example, in a plan view of the thermocouple 10t.

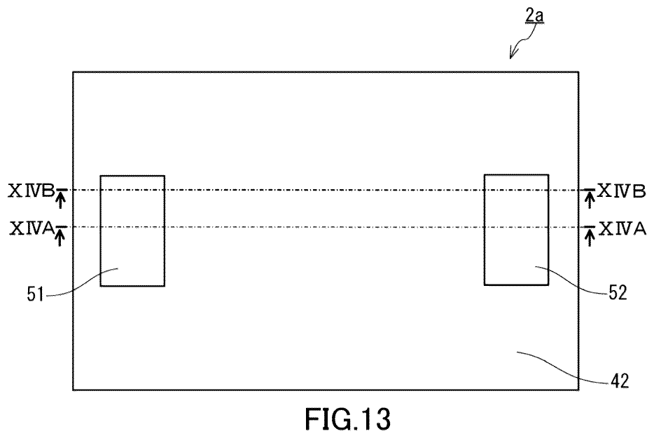

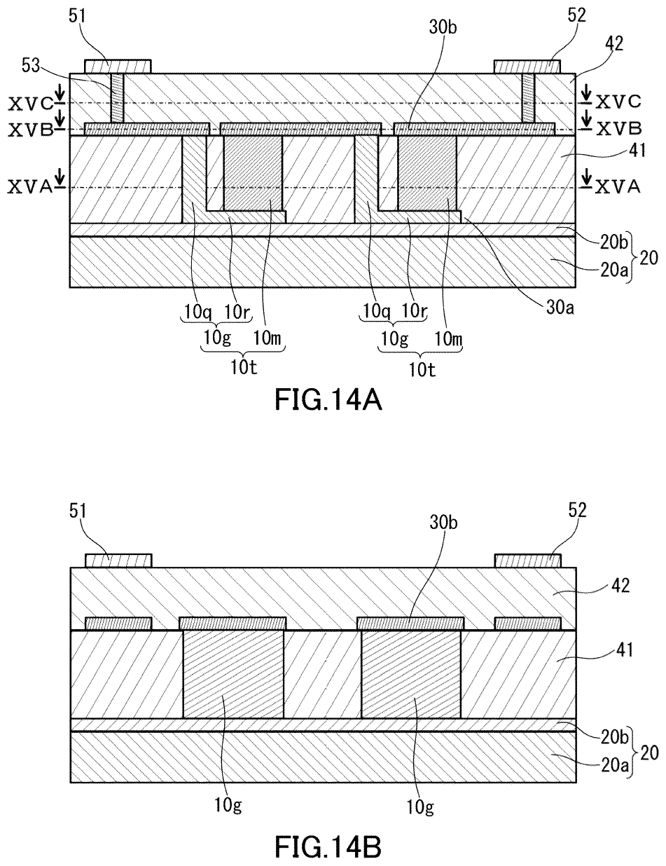

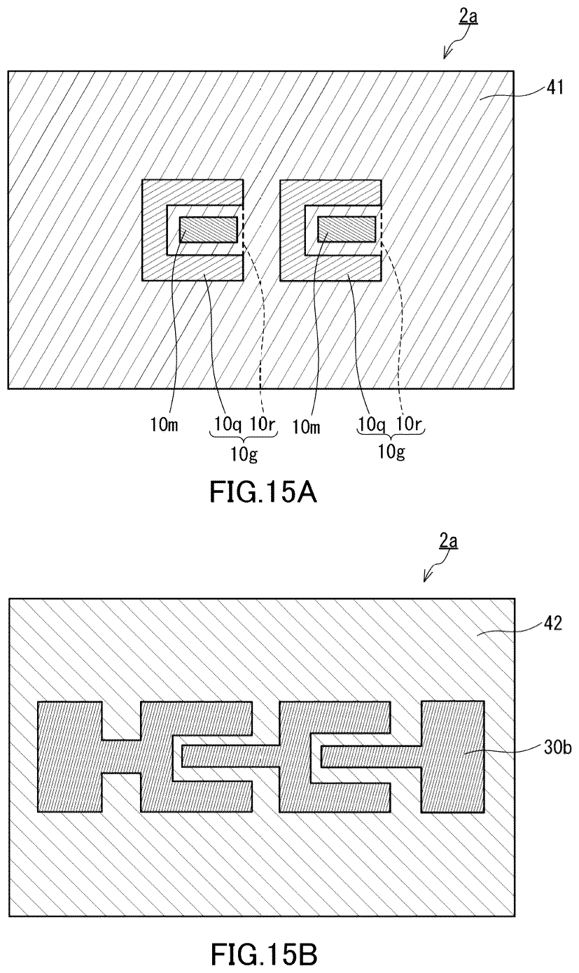

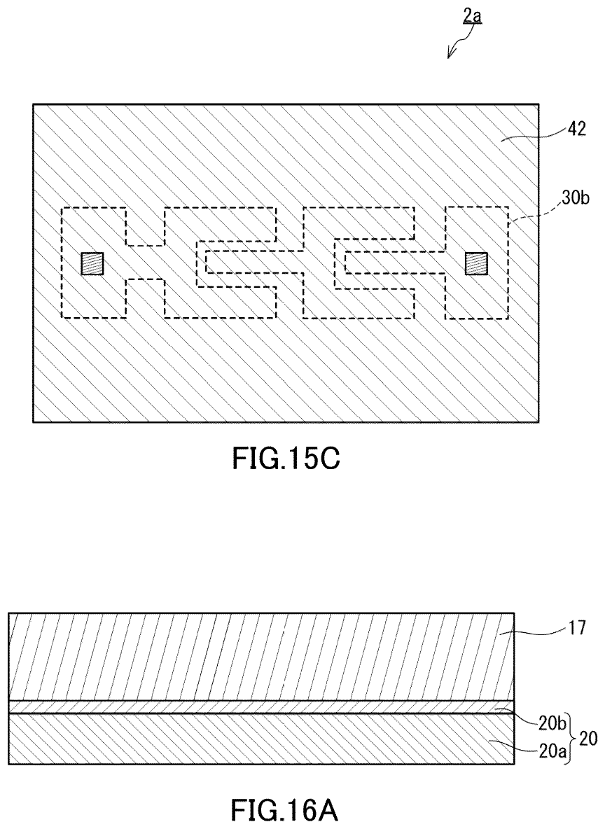

FIG. 13 is another plan view showing the thermoelectric conversion element 2a. FIG. 14A and FIG. 14B are sectional views of the thermoelectric conversion element 2a taken along line XIVA-XIVA and line XIVB-XIVB in FIG. 13, respectively. FIG. 15A, FIG. 15B, and FIG. 15C are sectional views of the thermoelectric conversion element 2a taken along line XVA-XVA, line XVB-XVB, and line XVC-XVC in FIG. 14A, respectively.

As shown in FIG. 14A and FIG. 15A, the thermoelectric conversion element 2a includes a plurality of thermocouples 10t. As shown in FIG. 14A, each thermoelectric member 10g is disposed on the foundation insulation film 20b of the substrate 20. Each electroconductive member 10m is disposed on the second portion 10r of the thermoelectric member 10g. A wiring 30 is disposed on the thermoelectric members 10g and the electroconductive members 10m. Thus, the thermoelectric members 10g and the electroconductive members 10m are electrically connected, and the thermocouples 10t are formed. The thermoelectric conversion element 2a further includes the first interlayer insulation film 41 and the second interlayer insulation film 42. The first interlayer insulation film 41 is formed so as to fill a gap between the thermoelectric member 10g and the electroconductive member 10m, and a space around the thermoelectric member 10g and the electroconductive member 10m. The second interlayer insulation film 42 is formed on the first interlayer insulation film 41, and covers the wiring 30. The thermoelectric conversion element 2a includes a plurality of plugs 53. The plugs 53 extend through the second interlayer insulation film 42 and are disposed on the wiring 30. The plugs 53 are electrically connected to the wiring 30. The first electrode pad 51 and the second electrode pad 52 are disposed on the second interlayer insulation film 42. The first electrode pad 51 and the second electrode pad 52 are electrically connected to different plugs 53, respectively. Thus, between the first electrode pad 51 and the second electrode pad 52, one thermocouple 10t is electrically connected to the other thermocouple 10t. In addition, by layers being laminated as described above, the thermocouples 10t are connected electrically in series.

A material forming the electroconductive member 10g is metal or a metal compound. Examples of the metal and the metal compound are materials, such as Al, Cu, W, TiN, and TaN, used in a semiconductor manufacturing process. As materials forming the members of the thermoelectric conversion element 2a, the materials described for the thermoelectric conversion element of embodiment 1 can be used.

An example of a method for manufacturing the thermoelectric conversion element 2a will be described. The method for manufacturing the thermoelectric conversion element 2a is not limited to the following method.

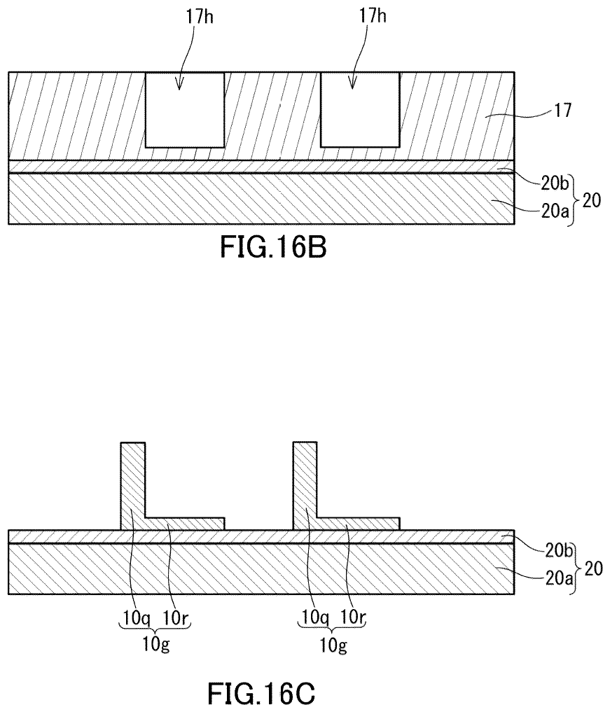

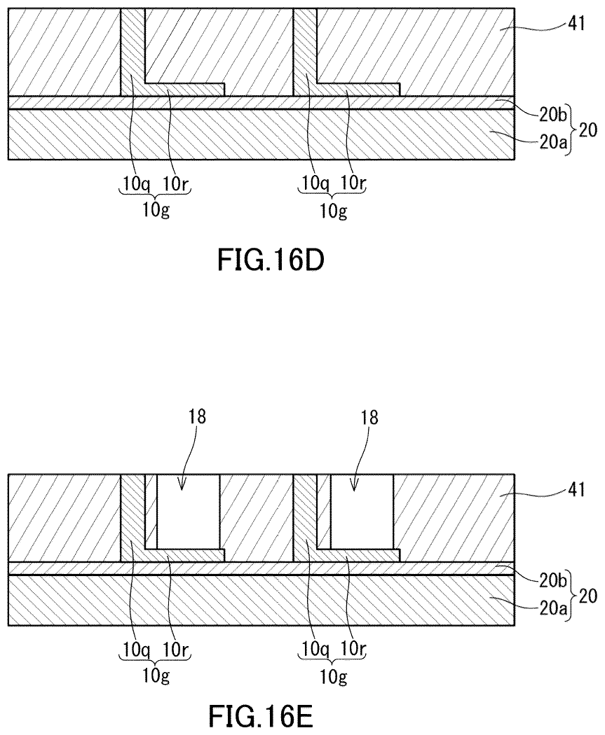

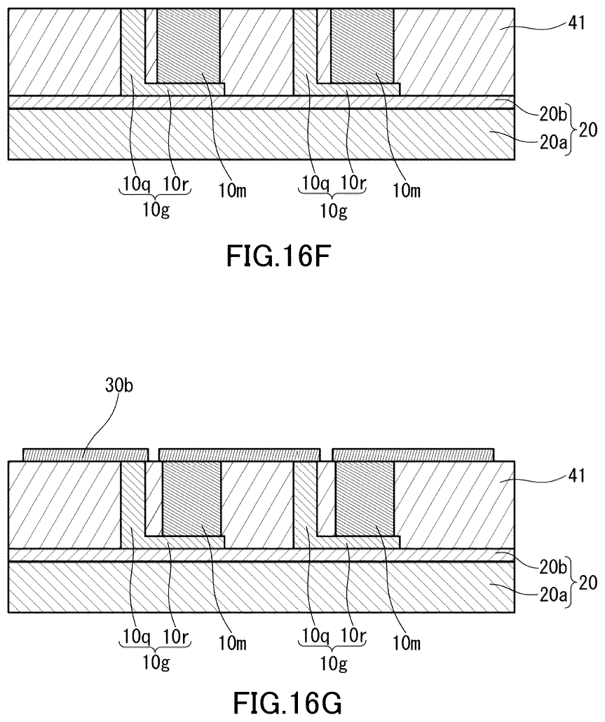

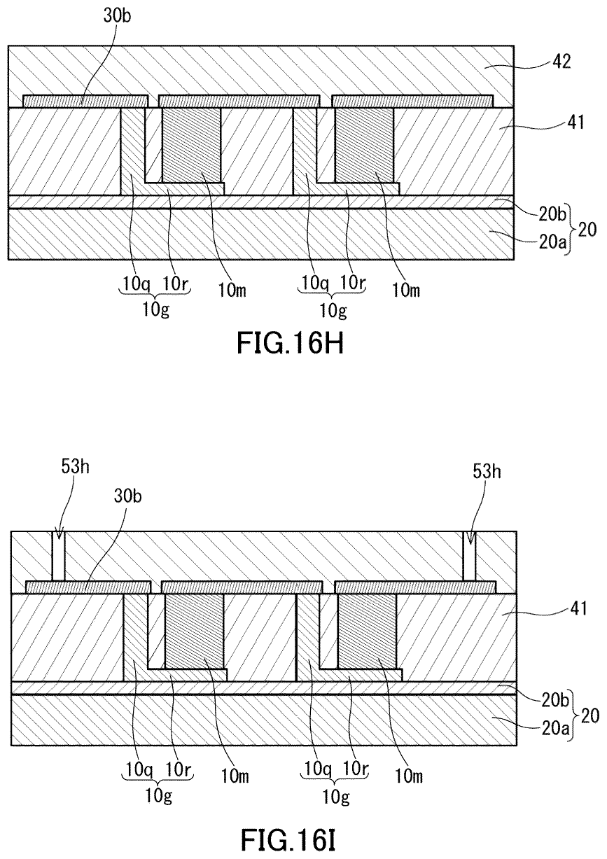

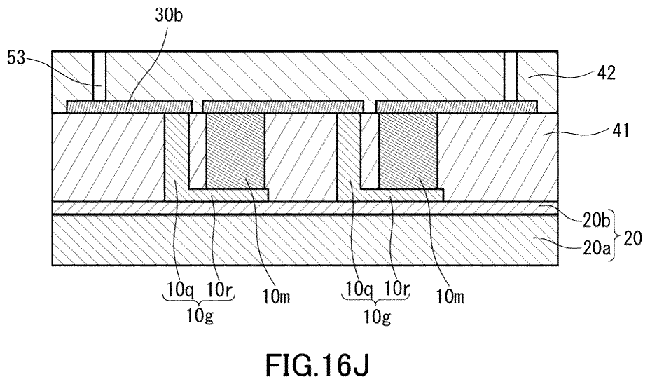

As shown in FIG. 16A, on one principal surface of the base 20a, the foundation insulation film 20b is formed. The base 20a is an Si substrate, for example. The foundation insulation film 20b is an electric insulator such as SiO₂ and is formed by a method such as sputtering or CVD, for example. On the foundation insulation film 20b, the thermoelectric material thin film 17 is formed. The thermoelectric material thin film 17 is a semiconductor such as polycrystal Si and is formed by a method such as sputtering or CVD, for example. A laminate of the base 20a, the foundation insulation film 20b, and the thermoelectric material thin film 17 may be replaced with a silicon-on-insulator (SOI) substrate. In the SOI substrate, a layer corresponding to the foundation insulation film 20b is a layer of SiO₂, and a layer corresponding to the thermoelectric material thin film 17 is a layer of single-crystal Si.

Next, the thermoelectric material thin film 17 is doped with impurity ions and the carrier density of electrons or holes is adjusted into a range of 1×10¹⁹ cm⁻³ to 1×10²¹ cm⁻³. The doping is performed by a method such as ion implantation and thermal diffusion, for example. An annealing treatment may be additionally performed to adjust the carrier density to a desired value. The doping may be performed for the entire surface of the thermoelectric material thin film 17, or may be performed for a predetermined area thereof using photolithography.

Next, as shown in FIG. 16B, recesses 17h are formed in predetermined areas of the thermoelectric material thin film 17 by photolithography and etching. The depths of the recesses 17h are adjusted in consideration of the second thicknesses of the second portions 10r. For example, the etching rate for the thermoelectric material thin film 17 is measured in advance and the time for etching is adjusted on the basis of the measurement result, whereby the depths of the recesses 17h can be adjusted into a range suitable to the second thicknesses of the second portions 10r.

Next, as shown in FIG. 16C, the thermoelectric members 10g are formed by photolithography and etching. Next, the first interlayer insulation film 41 made of a material such as SiO₂ is formed by a method such as sputtering and CVD from above the thermoelectric members 10g, so as to cover the thermoelectric members 10g. Then, as shown in FIG. 16D, of the first interlayer insulation film 41, a portion above the thermoelectric members 10g is removed by a method such as CMP.

Next, as shown in FIG. 16E, recesses 18 are formed in predetermined areas of the first interlayer insulation film 41 by photolithography and etching. At this stage, parts of the second portions 10r are exposed on bottom surfaces of the recesses 18. Next, a thin film of a material such as Al and TiN is formed by a method such as sputtering and CVD from above the first interlayer insulation film 41, so that the recesses 18 are filled. Next, as shown in FIG. 16F, the thin film outside the recesses 18 is removed by a method such as CMP, whereby the electroconductive members 10m are formed so as to fill the recesses 18.

Next, as shown in FIG. 16G, the wiring 30 made of an electric conductor such as Al is formed. A pattern to be the wiring 30 is formed by photolithography and etching, or lift-off, from a film of Al formed by a method such as sputtering.

Next, as shown in FIG. 16H, the second interlayer insulation film 42 is formed so as to cover the wiring 30. Next, as shown in FIG. 16I, recesses 53h are formed in the second interlayer insulation film 42 by photolithography and etching. At this stage, parts of the wiring 30 are exposed on bottom surfaces of the recesses 53h.

Next, a thin film of a material such as Al and TiN is formed by a method such as sputtering and CVD from above the second interlayer insulation film 42, so that the recesses 53h are filled. Then, as shown in FIG. 16J, the thin film outside the recesses 53h is removed by a method such as CMP, whereby the plugs 53 are formed. Finally, the first electrode pad 51 and the second electrode pad 52 are formed by lift-off, or photolithography and etching, from a metal thin film containing a material such as Al formed on the second interlayer insulation film 42. Thus, the thermoelectric conversion element 2a is manufactured.

### Additional Notes

From the above description, the following technologies are disclosed.

### Technology 1

A thermoelectric conversion element comprising:
a substrate; and
a plurality of thermocouples each including a thin-film-shaped p-type thermoelectric member and a thin-film-shaped n-type thermoelectric member arranged along a principal surface of the substrate, wherein
the thermoelectric conversion element generates a heat flow in a direction perpendicular to the principal surface of the substrate by a current in the thermocouples, and
in each of the thermocouples,
   the p-type thermoelectric member and the n-type thermoelectric member have a first side surface and a second side surface, respectively, and
   the first side surface and the second side surface face each other in a plurality of different directions.

With this configuration, electric charges flow into the thin-film-shaped thermoelectric members from a plurality of directions. Thus, non-uniformity of the current densities in the thin-film-shaped thermoelectric members is likely to become low, so that the performance of the thermoelectric conversion element is likely to be improved.

### Technology 2

The thermoelectric conversion element according to technology 1, wherein
at least one condition selected from the group consisting of the following (Ia) and (IIa) is satisfied:
(Ia) a first normal and a second normal can be defined on the p-type thermoelectric member,
the first normal extends from a first point of the first side surface toward outside of the p-type thermoelectric member, and intersects the second side surface,
the second normal extends from a second point different from the first point of the first side surface toward outside of the p-type thermoelectric member, and intersects the second side surface, and
the second normal extends in a direction having an angle that is 90 degrees or greater and 270 degrees or smaller counterclockwise with respect to the first normal when the thermocouple is seen in a plan view toward the substrate; and
(IIa) a third normal and a fourth normal can be defined on the n-type thermoelectric member,
the third normal extends from a third point of the second side surface toward outside of the n-type thermoelectric member, and intersects the first side surface,
the fourth normal extends from a fourth point different from the third point of the second side surface toward outside of the n-type thermoelectric member, and intersects the first side surface, and
the fourth normal extends in a direction having an angle that is 90 degrees or greater and 270 degrees or smaller counterclockwise with respect to the third normal when the thermocouple is seen in a plan view toward the substrate.

With this configuration, the above angle regarding the first normal and the second normal or the above angle regarding the third normal and the fourth normal is likely to be adjusted. Thus, non-uniformity of the current densities in the p-type thermoelectric member and the n-type thermoelectric member is more likely to become low.

### Technology 3

A thermoelectric conversion element comprising:
a substrate; and
a plurality of thermocouples each including a thin-film-shaped thermoelectric member and an electroconductive member arranged along a principal surface of the substrate, wherein
the electroconductive member contains at least one selected from the group consisting of metal and a metal compound
the thermoelectric conversion element generates a heat flow in a direction perpendicular to the principal surface of the substrate by a current in the thermocouples, and
in each of the thermocouples,
   the thermoelectric member and the electroconductive member have a first side surface and a second side surface, respectively, and
   the first side surface and the second side surface face each other in a plurality of different directions.

With this configuration, electric charges flow into the thin-film-shaped thermoelectric members from a plurality of directions. Thus, non-uniformity of the current densities in the thin-film-shaped thermoelectric members is likely to become low, so that the performance of the thermoelectric conversion element is likely to be improved.

### Technology 4

The thermoelectric conversion element according to technology 3, wherein
at least one condition selected from the group consisting of the following (Ib) and (IIb) is satisfied:
(Ib) a first normal and a second normal can be defined on the thermoelectric member,
the first normal extends from a first point of the first side surface toward outside of the thermoelectric member, and intersects the second side surface,
the second normal extends from a second point different from the first point of the first side surface toward outside of the thermoelectric member, and intersects the second side surface, and
the second normal extends in a direction having an angle that is 90 degrees or greater and 270 degrees or smaller counterclockwise with respect to the first normal when the thermocouple is seen in a plan view toward the substrate; and
(IIb) a third normal and a fourth normal can be defined on the electroconductive member,
the third normal extends from a third point of the second side surface toward outside of the electroconductive member, and intersects the first side surface,
the fourth normal extends from a fourth point different from the third point of the second side surface toward outside of the electroconductive member, and intersects the first side surface, and
the fourth normal extends in a direction having an angle that is 90 degrees or greater and 270 degrees or smaller counterclockwise with respect to the third normal when the thermocouple is seen in a plan view toward the substrate.

With this configuration, the above angle regarding the first normal and the second normal or the above angle regarding the third normal and the fourth normal is likely to be adjusted. Thus, non-uniformity of the current densities in the thermoelectric members is likely to become lower.

### Technology 5

The thermoelectric conversion element according to technology 3 or 4, wherein
the thermoelectric member has a first portion having a first thickness, and a second portion having a second thickness smaller than the first thickness, and
a step is formed by the first portion and the second portion.

With this configuration, a configuration corresponding to the first wiring 30a of the thermoelectric conversion element of embodiment 1 can be omitted. Thus, the configuration of the thermoelectric conversion elements is likely to be simplified.

### Technology 6

The thermoelectric conversion element according to technology 5, wherein
the electroconductive member is disposed on the second portion.

With this configuration, electric connection between the electroconductive member and the thermoelectric member can be ensured even if a configuration corresponding to the first wiring 30a of the thermoelectric conversion element of embodiment 1 is omitted.

### INDUSTRIAL APPLICABILITY

The thermoelectric conversion element of the present disclosure is applicable to various purposes including purposes of electric generation and temperature control, for example.

What is claimed is:

1. A thermoelectric conversion element comprising:
a substrate; and
a plurality of thermocouples each including a thin-film-shaped p-type thermoelectric member and a thin-film-shaped n-type thermoelectric member arranged along a principal surface of the substrate, wherein
the thermoelectric conversion element generates a heat flow in a direction perpendicular to the principal surface of the substrate by a current in the thermocouples, and
in each of the thermocouples,
the p-type thermoelectric member and the n-type thermoelectric member have a first side surface and a second side surface, respectively, and
the first side surface and the second side surface face each other in a plurality of different directions.

2. The thermoelectric conversion element according to claim 1, wherein
at least one condition selected from the group consisting of the following (Ia) and (IIa) is satisfied:
(Ia) a first normal and a second normal can be defined on the p-type thermoelectric member,
the first normal extends from a first point of the first side surface toward outside of the p-type thermoelectric member, and intersects the second side surface,
the second normal extends from a second point different from the first point of the first side surface toward outside of the p-type thermoelectric member, and intersects the second side surface, and
the second normal extends in a direction having an angle that is 90 degrees or greater and 270 degrees or smaller counterclockwise with respect to the first normal when the thermocouple is seen in a plan view toward the substrate; and
(IIa) a third normal and a fourth normal can be defined on the n-type thermoelectric member,
the third normal extends from a third point of the second side surface toward outside of the n-type thermoelectric member, and intersects the first side surface,
the fourth normal extends from a fourth point different from the third point of the second side surface toward outside of the n-type thermoelectric member, and intersects the first side surface, and
the fourth normal extends in a direction having an angle that is 90 degrees or greater and 270 degrees or smaller counterclockwise with respect to the third normal when the thermocouple is seen in a plan view toward the substrate.

3. A thermoelectric conversion element comprising:
a substrate; and
a plurality of thermocouples each including a thin-film-shaped thermoelectric member and an electroconductive member arranged along a principal surface of the substrate, wherein
the electroconductive member contains at least one selected from the group consisting of metal and a metal compound
the thermoelectric conversion element generates a heat flow in a direction perpendicular to the principal surface of the substrate by a current in the thermocouples, and
in each of the thermocouples,
the thermoelectric member and the electroconductive member have a first side surface and a second side surface, respectively, and
the first side surface and the second side surface face each other in a plurality of different directions.

4. The thermoelectric conversion element according to claim 3, wherein
at least one condition selected from the group consisting of the following (Ib) and (IIb) is satisfied:
(Ib) a first normal and a second normal can be defined on the thermoelectric member,
the first normal extends from a first point of the first side surface toward outside of the thermoelectric member, and intersects the second side surface,
the second normal extends from a second point different from the first point of the first side surface toward outside of the thermoelectric member, and intersects the second side surface, and
the second normal extends in a direction having an angle that is 90 degrees or greater and 270 degrees or smaller counterclockwise with respect to the first normal when the thermocouple is seen in a plan view toward the substrate; and
(IIb) a third normal and a fourth normal can be defined on the electroconductive member,
the third normal extends from a third point of the second side surface toward outside of the electroconductive member, and intersects the first side surface,
the fourth normal extends from a fourth point different from the third point of the second side surface toward outside of the electroconductive member, and intersects the first side surface, and
the fourth normal extends in a direction having an angle that is 90 degrees or greater and 270 degrees or smaller counterclockwise with respect to the third normal when the thermocouple is seen in a plan view toward the substrate.

5. The thermoelectric conversion element according to claim 3, wherein
the thermoelectric member has a first portion having a first thickness, and a second portion having a second thickness smaller than the first thickness, and
a step is formed by the first portion and the second portion.

6. The thermoelectric conversion element according to claim 5, wherein
the electroconductive member is disposed on the second portion.
